(19) United States
(12) Patent Application Publication
(10) Pub. No.: US 2024/0209284 A1
(43) Pub. Date: Jun. 27, 2024

(54) CLEANING COMPOSITION, CLEANING METHOD OF SEMICONDUCTOR SUBSTRATE, AND MANUFACTURING METHOD OF SEMICONDUCTOR ELEMENT

(71) Applicant: FUJIFILM Corporation, Tokyo (JP)

(72) Inventors: Naotsugu MURO, Haibara-gun (JP); Tadashi Inaba, Haibara-gun (JP); Tetsuya Kamimura, Haibara-gun (JP)

(73) Assignee: FUJIFILM Corporation, Tokyo (JP)

(21) Appl. No.: 18/533,556

(22) Filed: Dec. 8, 2023

Related U.S. Application Data
(63) Continuation of application No. PCT/JP22/23423, filed on Jun. 10, 2022.

(30) Foreign Application Priority Data
Jun. 14, 2021 (JP) 2021-098727
Jun. 9, 2022 (JP) 2022-093383

(51) Int. Cl. C11D 1/22; C11D 3/20; C11D 3/33; C11D 3/36; H01L 21/02

(52) U.S. Cl. CPC C11D 1/22; C11D 3/2082; C11D 3/2086; C11D 3/33; C11D 3/361; C11D 3/364; H01L 21/02074

(57) ABSTRACT

The present invention provides a cleaning composition having excellent storage stability, a cleaning method of a semiconductor substrate, and a manufacturing method of a semiconductor element. The cleaning composition of the present invention contains a polycarboxylic acid, a chelating agent, a sulfonic acid having an alkyl group having 9 to 18 carbon atoms, and water, in which a mass ratio of the polycarboxylic acid to the chelating agent is 10 to 200, a mass ratio of the polycarboxylic acid to the sulfonic acid is 70 to 1,000, a pH is 0.10 to 4.00, and an electrical conductivity is 0.08 to 11.00 mS/cm.

### CROSS-REFERENCE TO RELATED APPLICATIONS

This application is a Continuation of PCT International Application No. PCT/JP2022/023423 filed on Jun. 10, 2022, which claims priority under 35 U.S.C. § 119(a) to Japanese Patent Application No. 2021-098727 filed on Jun. 14, 2021 and Japanese Patent Application No. 2022-093383 filed on Jun. 9, 2022. The above applications are hereby expressly incorporated by reference, in their entirety; into the present application.

### BACKGROUND OF THE INVENTION

### 1. Field of the Invention

The present invention relates to a cleaning composition, a cleaning method of a semiconductor substrate, and a manufacturing method of a semiconductor element.

### 2. Description of the Related Art

A cleaning composition is used for the purpose of removing foreign substances and the like in various field. For example, the cleaning composition is used in the following applications in the semiconductor field.

Semiconductor elements such as a charge-coupled device (CCD) and a memory are manufactured by forming a fine electronic circuit pattern on a substrate using a photolithographic technique. Specifically, the semiconductor elements are manufactured by forming a resist film on a laminate which has a metal film serving as a wiring line material, an etching stop layer, and an interlayer insulating layer on a substrate, and carrying out a photolithography step and a dry etching step (for example, a plasma etching treatment).

In the manufacture of the semiconductor element, a chemical mechanical polishing (CMP) treatment in which a surface of a semiconductor substrate having a metal wiring line film, a barrier metal, an insulating film, or the like is flattened using a polishing slurry containing polishing fine particles (for example, silica and alumina) or the like may be carried out. In the CMP treatment, the polishing fine particles to be used in the CMP treatment, a polished wiring line metal film, and/or a metal component derived from the barrier metal or the like easily remain on the surface of the semiconductor substrate after polishing. Since these residues can short-circuit wiring lines and affect electrical characteristics of a semiconductor, a cleaning step in which these residues are removed from the surface of the semiconductor substrate is generally carried out.

As a cleaning composition used in the cleaning step, for example, JP2005-255983A discloses “composition for cleaning used after a chemical mechanical polishing, the composition containing organic polymer particles (A) having a crosslinking structure and a surfactant (B)”.

### SUMMARY OF THE INVENTION

As a result of studying the cleaning composition disclosed in JP2005-255983A, the present inventors have found that storage stability is deteriorated.

For example, after storing the cleaning composition disclosed in JP2005-255983A, the present inventors have studied on cleaning performance and anticorrosion performance for a semiconductor substrate including a metal film subjected to the CMP treatment, using the obtained cleaning composition. As a result, it has been found that, as storage time over time increases, at least one of the cleaning performance or the anticorrosion performance of the cleaning composition deteriorates.

Hereinafter, “excellent in storage stability” is intended to mean excellent in both cleaning performance and anticorrosion performance after storing a cleaning composition for a certain period of time.

An object of the present invention is to provide a cleaning composition having excellent storage stability.

Another object of the present invention is to provide a cleaning method of a semiconductor substrate and a manufacturing method of a semiconductor element.

The present inventor has found that the above-described objects can be achieved by the following configurations.
[1]
A cleaning composition comprising:
a polycarboxylic acid:
a chelating agent:
a sulfonic acid having an alkyl group having 9 to 18 carbon atoms; and water,
in which a mass ratio of the polycarboxylic acid to the chelating agent is 10 to 200,
a mass ratio of the polycarboxylic acid to the sulfonic acid is 70 to 1,000,
a pH of the cleaning composition is 0.10 to 4.00, and
an electrical conductivity of the cleaning composition is 0.08 to 11.00 mS/cm.
[2]
The cleaning composition according to [1],
in which the polycarboxylic acid includes a polycarboxylic acid having two or three carboxy groups.
[3]
The cleaning composition according to [1] or [2],
in which the polycarboxylic acid further includes a polycarboxylic acid having a hydroxy group.
[4]
The cleaning composition according to any one of [1] to [3],
in which the polycarboxylic acid includes citric acid.
[5]
The cleaning composition according to any one of [1] to [4],
in which a content of the polycarboxylic acid is 0.1% to 35% by mass with respect to a total mass of the cleaning composition.
[6]
The cleaning composition according to any one of [1] to [5],
in which the sulfonic acid is alkylbenzenesulfonic acid.
[7]
The cleaning composition according to any one of [1] to [6],
in which the sulfonic acid has any alkyl group having 10 to 13 carbon atoms.
[8]
The cleaning composition according to any one of [1] to [7],
in which the sulfonic acid includes an alkylbenzenesulfonic acid A having an alkyl group having 10 carbon atoms, an alkylbenzenesulfonic acid B having an alkyl group having 11 carbon atoms, an alkylbenzenesulfonic acid C having an alkyl group having 12 carbon atoms, and an alkylbenzenesulfonic acid D having an alkyl group having 13 carbon atoms.
[9]
The cleaning composition according to [8],
in which a content of the alkylbenzenesulfonic acid B is 20% to 50% by mass with respect to a total mass of the alkylbenzenesulfonic acids A to D.
[10]
The cleaning composition according to any one of [1] to [9],
in which the chelating agent has a phosphonate group.
[11]
The cleaning composition according to any one of [1] to [10],
in which the mass ratio of the polycarboxylic acid to the chelating agent is 30 to 100.
[12]
The cleaning composition according to any one of [1] to [11],
in which the mass ratio of the polycarboxylic acid to the sulfonic acid is 70 to 600.
[13]
The cleaning composition according to any one of [1] to [12], further comprising:
a phosphate ion,
in which a content of the phosphate ion is 0.001% to 1.0% by mass with respect to a total mass of the cleaning composition.
[14]
A cleaning method of a semiconductor substrate, comprising:
cleaning a semiconductor substrate with the cleaning composition according to any one of [1] to [13].
[15]
A manufacturing method of a semiconductor element, comprising:
the cleaning method of a semiconductor substrate according to [14].

According to the present invention, it is possible to provide a cleaning composition having excellent storage stability.

In addition, according to the present invention, it is possible to provide a cleaning method of a semiconductor substrate and a manufacturing method of a semiconductor element.

### DESCRIPTION OF THE PREFERRED EMBODIMENTS

Hereinafter, an example of forms for carrying out the present invention will be described.

The meaning of each notation in the present specification is shown below.

A numerical range represented using “to” means a range including numerical values described before and after the preposition “to” as a lower limit and an upper limit.

“ppm” means “parts-per-million (10⁻⁶)”, and “ppb” means “parts-per-billion (10⁻⁹)”. “psi” means pound-force per square inch, where 1 psi=6,894.76 Pa.

In a case where there are two or more components corresponding to a certain component, “content” of such a component means the total content of the two or more components.

Unless otherwise specified, compounds described in the present specification may include structural isomers, optical isomers, and isotopes. In addition, one kind of structural isomer, optical isomer, and isotope may be included, or two or more kinds thereof may be included.

A bonding direction of a divalent group cited (for example, —COO—) is not limited unless otherwise specified. For example, in a case where Y in a compound represented by a formula “X—Y—Z” is —COO—, the compound may be “X—O—CO—Z” or “X—CO—O—Z”.

“Weight-average molecular weight” means a weight-average molecular weight in terms of polyethylene glycol measured by gel permeation chromatography (GPC).

A phrase “on the semiconductor substrate” encompasses, for example, front and back surfaces, a side surface, and the inside of a groove of the semiconductor substrate. In addition, a metal-containing substance on the semiconductor substrate encompasses not only a case where the metal-containing substance is directly on the surface of the semiconductor substrate but also a case where the metal-containing substance is present on the semiconductor substrate through another layer.

### Cleaning Composition

The cleaning composition according to the embodiment of the present invention contains a polycarboxylic acid, a chelating agent, a sulfonic acid having an alkyl group having 9 to 18 carbon atoms, and water,
in which a mass ratio of the polycarboxylic acid to the chelating agent is 10 to 200,
a mass ratio of the polycarboxylic acid to the sulfonic acid is 70 to 1,000,
a pH of the cleaning composition is 0.10 to 4.00, and
an electrical conductivity of the cleaning composition is 0.08 to 11.00 mS/cm.

A mechanism by which the objects of the present invention are achieved through the above-described configuration is not always clear, but is presumed by the present inventors to be as follows.

In a case where the cleaning composition according to the embodiment of the present invention satisfies the predetermined requirements, it is presumed that the compounds interact with each other to provide excellent storage stability.

Hereinafter, the fact that the storage stability is also referred to “the effect of the present invention is more excellent”.

Hereinafter, each component contained in the cleaning composition will be described.

### Polycarboxylic Acid

The cleaning composition contains a polycarboxylic acid.

The polycarboxylic acid is a compound having two or more carboxy groups in a molecule.

The polycarboxylic acid is a compound different from a chelating agent described later. It is preferable that the polycarboxylic acid does not have an amino group as a functional group. In addition, the polycarboxylic acid may have a functional group other than the carboxy group. As the other functional group, a hydroxy group is preferable.

The number of carboxy groups included in the polycarboxylic acid is preferably 2 to 10 and more preferably 2 or 3.

The number of hydroxy groups included in the polycarboxylic acid is preferably 1 to 3 and more preferably 1.

It is preferable that the polycarboxylic acid includes a polycarboxylic acid having two or three carboxy groups. It is also preferable to include a polycarboxylic acid further having a hydroxy group in addition to the carboxy group, and it is more preferable to include a polycarboxylic acid having two or three carboxy groups and having a hydroxy group.

The polycarboxylic acid may be in a form of salt.

The polycarboxylic acid is preferably a compound represented by Formula (D1).

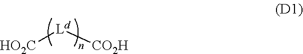

In Formula (D1), L^{d} represents —CR^{d1}R^{d2}— or an alkenyl group which may have a substituent. R^{d1} and R^{d2} each independently represent a hydrogen atom, a hydroxy group, or a carboxy group. n represents an integer of 0 to 5.

L^{d} represents —CR^{d1}R^{d2}— or an alkenyl group which may have a substituent. R^{d1} and R^{d2} each independently represent a hydrogen atom, a hydroxy group, or a carboxy group.

The number of carbon atoms in the above-described alkenyl group is preferably 2 to 10 and more preferably 2 to 5.

The above-described alkenyl group may be linear, branched, or cyclic, and is preferably linear.

Examples of the substituent included in the above-described alkenyl group include a halogen atom such as a fluorine atom, a chlorine atom, and a bromine atom, a hydroxy group, and a carboxy group. In addition, the above-described alkenyl group is also preferably an unsubstituted alkenyl group. The above-described alkenyl group is preferably a vinylene group.

The total number of hydroxy groups represented by R^{d1} and R^{d2} is preferably 0 to 4, more preferably 1 or 2, and still more preferably 1.

The total number of carboxy groups represented by R^{d1} and R^{d2} is preferably 0 to 4, more preferably 1 or 2, and still more preferably 1.

The total number of hydroxy groups represented by R^{d1} and R^{d2} and carboxy groups represented by R^{d1} and R^{d2} is preferably 0 to 8, more preferably 2 to 4, and still more preferably 2.

A plurality of R^{d1}'s, a plurality of R^{d2}'s, and a plurality of L^{d}'s may be the same or different from each other, respectively.

n represents an integer of 0 to 5.

n is preferably an integer of 0 to 4, more preferably an integer of 0 to 3, and still more preferably an integer of 1 to 3.

Examples of the polycarboxylic acid include an aliphatic polycarboxylic acid.

Examples of the aliphatic polycarboxylic acid include citric acid, oxalic acid, tartaric acid, malic acid, maleic acid, malonic acid, succinic acid, glutaric acid, adipic acid, pimelic acid, and sebacic acid: and at least one selected from the group consisting of citric acid, oxalic acid, tartaric acid, malic acid, and maleic acid is preferable and citric acid is more preferable.

In addition, it is also preferable that the polycarboxylic acid consists of only citric acid.

A molecular weight of the polycarboxylic acid is preferably 70 to 400, more preferably 80 to 300, and still more preferably 120 to 200.

The polycarboxylic acid may be used alone or in combination of two or more kinds thereof.

A content of the polycarboxylic acid is usually 0.001% to 35% by mass with respect to the total mass of the cleaning composition, preferably 0.1% to 35% by mass, more preferably 1.0% to 35% by mass, still more preferably 3.0% to 35% by mass, even more preferably 10.0% to 35% by mass, and particularly preferably 20.0% to 35% by mass.

Among these, in a case of being the suitable aspect of the above-described content of the polycarboxylic acid, the polycarboxylic acid preferably includes at least one selected from the group consisting of citric acid and malic acid, and more preferably consists of only at least one selected from the group consisting of citric acid and malic acid.

In addition, in a case where the polycarboxylic acid includes tartaric acid (preferably, consists of only tartaric acid), as another suitable aspect, the content of the polycarboxylic acid is preferably 0.01% to 30% by mass, more preferably 0.5% to 30% by mass, still more preferably 1.0% to 10% by mass, and particularly preferably 3.0% to 10% by mass.

In addition, in a case where the polycarboxylic acid includes oxalic acid (preferably, consists of only oxalic acid), as another suitable aspect, the content of the polycarboxylic acid is preferably 0.01% to 20% by mass and more preferably 0.1% to 10% by mass.

In addition, in a case where the polycarboxylic acid includes at least one selected from the group consisting of maleic acids (preferably, consists of only maleic acid), as another suitable aspect, the content of the polycarboxylic acid is preferably 0.01% to 20% by mass, more preferably 0.1% to 10% by mass, and still more preferably 0.5% to 10% by mass.

### Chelating Agent

The cleaning composition contains a chelating agent.

The chelating agent is a compound different from the above-described polycarboxylic acid. In addition, it is preferable that the chelating agent is a compound different from a specific sulfonic acid, a surfactant, and other components described later.

Examples of the chelating agent include organic acid, examples of the organic acid include a carboxylic acid-based organic acid and a phosphonic acid-based organic acid, and a phosphonic acid-based organic acid is preferable.

The chelating agent may be in a form of salt.

Examples of an acid group included in the organic acid (chelating agent) include a carboxy group, a phosphonate group, a sulfo group, and a phenolic hydroxy group.

The organic acid (chelating agent) preferably has at least one selected from the group consisting of a carboxy group and a phosphonate group, and more preferably has a phosphonate group.

The number of acid groups included in the organic acid (chelating agent) is preferably 1 to 5 and more preferably 2 to 4.

### <Carboxylic Acid-Based Organic Acid>

The carboxylic acid-based organic acid is an organic acid having at least one carboxy group in the molecule. The carboxylic acid-based organic acid is preferably a compound having only one carboxy group in the molecule or a compound having a carboxy group and an amino group in the molecule.

Examples of the carboxylic acid-based organic acid include an amino polycarboxylic acid-based organic acid and an amino acid-based organic acid.

Examples of the amino polycarboxylic acid-based organic acid include butylenediaminetetraacetic acid, diethylenetriaminepentacetic acid (DTPA), ethylenediaminetetrapropionic acid, triethylenetetraminehexacetic acid, 1,3-diamino-2-hydroxypropane-N,N,N′,N′-tetraacetic acid, propylenediaminetetraacetic acid, ethylenediaminetetraacetic acid (EDTA), trans-1,2-diaminocyclohexanetetraacetic acid, ethylenediaminediacetic acid, ethylenediaminedipropionic acid, 1,6-hexamethylene-diamine-N,N,N′,N′-tetraacetic acid, N,N-bis(2-hydroxy benzyl)ethylenediamine-N,N-diacetic acid, diaminopropanetetraacetic acid, 1,4,7,10-tetraazacyclododecane-tetraacetic acid, diaminopropanoltetraacetic acid, (hydroxyethyl)ethylenediaminetriacetic acid, and iminodiacetic acid (IDA): and ethylenediaminetetrapropionic acid (EDTA) is preferable.

Examples of the amino acid-based organic acid include glycine, serine, α-alanine and a salt thereof, β-alanine and a salt thereof, lysine, leucine, isoleucine, cystine, cysteine, ethionine, threonine, tryptophan, tyrosine, valine, histidine, a histidine derivative, asparagine, aspartic acid and a salt thereof, glutamine, glutamic acid and a salt thereof, arginine, proline, methionine, phenylalanine, and compounds described in paragraphs [0021] to [0023] of JP2016-086094A and a salt thereof.

Examples of the histidine derivative include compounds described in JP2015-165561A and JP2015-165562A, the contents of which are incorporated herein by reference.

In addition, examples of the salt include an alkali metal salt such as a sodium salt and a potassium salt, an ammonium salt, a carbonate, and an acetate.

### <Phosphonic Acid-Based Organic Acid>

The phosphonic acid-based organic acid is an organic acid having at least one phosphonate group in the molecule.

In a case where the chelating agent has a phosphonate group and a carboxy group, it is classified into the carboxylic acid-based organic acid.

Examples of the phosphonic acid-based organic acid include an aliphatic phosphonic acid-based organic acid and an amino phosphonic acid-based organic acid.

The aliphatic phosphonic acid-based organic acid may further have a hydroxy group in addition to the phosphonate group and the aliphatic group.

The number of phosphonate groups included in the phosphonic acid-based organic acid is preferably 2 to 5, more preferably 2 to 4, and still more preferably 2 or 3.

The number of carbon atoms in the phosphonic acid-based organic acid is preferably 1 to 12, more preferably 1 to 10, and still more preferably 1 to 3.

Examples of the phosphonic acid-based organic acid include 1-hydroxyethylidene-1,1′-diphosphonic acid (HEDPO), ethylidene diphosphonic acid, 1-hydroxypropyridene-1,1′-diphosphonic acid, and 1-hydroxy butylidene-1,1′-diphosphonic acid, ethylaminobis(methylenephosphonic acid), dodecylaminobis(methylenephosphonic acid), nitrilotris(methylenephosphonic acid) (NTPO), ethylenediaminebis(methylenephosphonic acid) (EDDPO), ethylenediaminetetramethy lenephosphonic acid (EDTMP), 1,3-propylenediaminebis(methylenephosphonic acid), ethylenediaminetetra(methylenephosphonic acid) (EDTPO), ethylenediaminetetra(ethylenephosphonic acid), 1,3-propylenediaminetetra(methylenephosphonic acid) (PDTMP), 1,2-diaminopropanetetra(methylenephosphonic acid), 1,6-hexamethylenediaminetetra(methylenephosphonic acid), diethylenetriaminepenta(methylenephosphonic acid) (DEPPO), diethylenetriaminepenta(ethy lenephosphonic acid), triethylenetetraminehexa(methylenephosphonic acid), triethylenetetraminehexa(ethylenephosphonic acid), and salts thereof; and HEDPO or EDTMP is preferable and HEDPO is more preferable.

In addition, examples of the salt include an alkali metal salt such as a sodium salt and a potassium salt, an ammonium salt, a carbonate, and an acetate.

Examples of the phosphonic acid-based organic acid include compounds described in paragraphs [0026] to [0036] of WO2018/020878A and compounds ((co)polymers) described in paragraphs [0031] to [0046] of WO2018/030006A, the content of which is incorporated herein by reference.

As a commercially available product of the phosphonic acid-based organic acid, a commercially available phosphonic acid-based organic acid containing a phosphonic acid-based organic acid and water such as distilled water, deionized water, and ultrapure water may be used.

A molecular weight of the chelating agent is preferably 600 or less, more preferably 450 or less, and still more preferably 300 or less. The lower limit thereof is usually 80 or more, preferably 100 or more.

The chelating agent may be used alone or in combination of two or more kinds thereof.

From the viewpoint that the performance of the cleaning composition is excellent in a well-balanced, a content of the chelating agent is usually 0.001% by mass or more with respect to the total mass of the cleaning composition, preferably 0.20% by mass or more, more preferably 0.25% by mass or more, still more preferably 0.35% by mass or more, particularly preferably 0.45% by mass or more, and most preferably 0.50% by mass or more. The upper limit thereof is usually 5.00% by mass or less with respect to the total mass of the cleaning composition, preferably 1.40% by mass or less, more preferably 1.10% by mass or less, still more preferably 0.90% by mass or less, particularly preferably 0.70% by mass or less, and most preferably 0.60% by mass or less.

### Specific Sulfonic Acid

The cleaning composition contains a specific sulfonic acid.

The specific sulfonic acid is a sulfonic acid having an alkyl group having 9 to 18 carbon

In addition, the specific sulfonic acid may be in a form of salt. atoms.

The specific sulfonic acid is a compound different from each of the above-described compounds.

The number of sulfonic acid groups included in the specific sulfonic acid is preferably 1 to 5, more preferably 1 to 3, and still more preferably 1.

The alkyl group included in the specific sulfonic acid may be linear, branched, or cyclic, and is preferably linear or branched and more preferably branched.

The number of carbon atoms in the above-described alkyl group is 9 to 18, preferably 10 to 15 and more preferably 10 to 13. The specific sulfonic acid may further have another alkyl group (for example, an alkyl group having 1 to 8 carbon atoms) as long as it has the alkyl group having 9 to 18 carbon atoms.

The specific sulfonic acid may have other groups in addition to the sulfonic acid group and the above-described alkyl group.

The other groups are preferably an aromatic ring group. The aromatic ring group may be monocyclic or polycyclic.

The number of aromatic ring groups included in the specific sulfonic acid is preferably 1 to 5, more preferably 1 to 3, and still more preferably 1.

The number of carbon atoms in the aromatic ring group is preferably 6 to 20, and more preferably 6 to 15.

Examples of a ring constituting the aromatic ring group include aromatic hydrocarbon rings such as a benzene ring and a naphthalene ring, and a benzene ring or a naphthalene ring is preferable and a benzene ring is more preferable.

The specific sulfonic acid preferably has any alkyl group having 10 to 13 carbon atoms. The fact of having any alkyl group having 10 to 13 carbon atoms means having any one of an alkyl group having 10 carbon atoms, an alkyl group having 11 carbon atoms, an alkyl group having 12 carbon atoms, or an alkyl group having 13 carbon atoms, and for example, an aspect of having an alkyl group having 10 carbon atoms and an alkyl group having 11 carbon atoms are not included therein. In addition, it is also preferable that the specific sulfonic acid includes an alkylbenzenesulfonic acid A having an alkyl group having 10 carbon atoms, an alkylbenzenesulfonic acid B having an alkyl group having 11 carbon atoms, an alkylbenzenesulfonic acid C having an alkyl group having 12 carbon atoms, and an alkylbenzenesulfonic acid D having an alkyl group having 13 carbon atoms. In other words, it is preferable that the specific sulfonic acid includes four or more kinds of alkylbenzenesulfonic acids.

The specific sulfonic acid is preferably a compound represented by Formula (A1).

R^{a}—Ar^{a}—SO₃H (A1)

In Formula (A1), R^{a} represents an alkyl group having 9 to 18 or more carbon atoms. Ar^{a} represents an arylene group.

R^{a} represents an alkyl group having 9 to 18 carbon atoms.

The above-described alkyl group has the same definition as the alkyl group having 9 to 18 carbon atoms included in the specific sulfonic acid described above, and suitable aspects thereof are also the same.

Ar^{a} represents an arylene group.

The above-described arylene group may be monocyclic or polycyclic. The number of carbon atoms in the arylene group is preferably 6 to 20 and more preferably 6 to 15.

As the arylene group, a phenylene group or a naphthylene group is preferable.

Examples of the specific sulfonic acid include alkylbenzenesulfonic acids and salts thereof, such as 4-(1-methyloctyl)benzenesulfonic acid, 4-(1-methylnonyl)benzenesulfonic acid, 4-(1-methyldecyl)benzenesulfonic acid, 4-(1-methylundecyl)benzenesulfonic acid, decylbenzenesulfonic acid, undecylbenzenesulfonic acid, dodecylbenzenesulfonic acid, tridecylbenzenesulfonic acid, and tetradecylbenzenesulfonic acid: alkylsulfonic acids and salts thereof, such as decylsulfonic acid, undecylsulfonic acid, dodecylsulfonic acid, tridecylsulfonic acid, and tetradecylsulfonic acid: and alkylnaphthalenesulfonic acids and salts thereof, such as 5-undecyl-2-naphthalenesulfonic acid, 5-dodecyl-2-naphthalenesulfonic acid, decylnaphthalenesulfonic acid, undecylnaphthalenesulfonic acid, dodecylnaphthalenesulfonic acid, tridecylnaphthalenesulfonic acid, and tetradecy lnaphthalenesulfonic acid.

The specific sulfonic acid is preferably alkylbenzenesulfonic acid.

In addition, examples of the above-described salt include an alkali metal salt such as a sodium salt and a potassium salt, and an ammonium salt.

A molecular weight of the specific sulfonic acid is preferably 100 to 1,000 and more preferably 200 to 500.

The specific sulfonic acid may be used alone or in combination of two or more kinds thereof.

A content of the specific sulfonic acid is usually 0.0001% by mass or more with respect to the total mass of the cleaning composition, preferably 0.03% by mass or more, more preferably 0.04% by mass or more, still more preferably 0.05% by mass or more, particularly preferably 0.06% by mass or more, and most preferably 0.07% by mass or more. The upper limit thereof is usually 1.00% by mass or less with respect to the total mass of the cleaning composition, preferably 0.40% by mass or less, more preferably 0.10% by mass or less, and still more preferably 0.08% by mass or less.

A content of the alkylbenzenesulfonic acid A is preferably 0% to 100% by mass, more preferably 1% to 30% by mass, still more preferably 3% to 20% by mass, and particularly preferably 7% to 15% by mass with respect to the total mass of the alkylbenzenesulfonic acids A to D.

A content of the alkylbenzenesulfonic acid B is preferably 0% to 100% by mass, more preferably 20% to 50% by mass, and still more preferably 30% to 40% by mass with respect to the total mass of the alkylbenzenesulfonic acids A to D.

A content of the alkylbenzenesulfonic acid C is preferably 0% to 100% by mass, more preferably 10% to 60% by mass, still more preferably 20% to 40% by mass, and particularly preferably 25% to 35% by mass with respect to the total mass of the alkylbenzenesulfonic acids A to D.

A content of the alkylbenzenesulfonic acid D is preferably 0% to 100% by mass, more preferably 10% to 50% by mass, still more preferably 15% to 40% by mass, and particularly preferably 20% to 30% by mass with respect to the total mass of the alkylbenzenesulfonic acids A to D.

### Water

The cleaning composition contains water.

The water is not particularly limited. Examples thereof include distilled water, deionized water, and pure water (ultrapure water). As the above-described water, pure water (ultrapure water) is preferable from the viewpoint that it includes almost no impurities and has less influence on a semiconductor substrate in a step of manufacturing the semiconductor substrate.

A content of the water is not particularly limited as long as it is a remainder of components which can be contained in the cleaning composition.

The content of the water is preferably 1.0% by mass or more, more preferably 30.0% by mass or more, still more preferably 50.0% by mass or more, and particularly preferably 60.0% by mass or more with respect to the total mass of the cleaning composition. The upper limit thereof is preferably 99.99% by mass or less, more preferably 99.9% by mass or less, still more preferably 99.0% by mass or less, and particularly preferably 97.0% by mass or less with respect to the total mass of the cleaning composition.

### Mass Ratio of Component

A mass ratio of the polycarboxylic acid to the chelating agent (mass of polycarboxylic acid/mass of chelating agent) is 10 to 200, and from the viewpoint that the effect of the present invention is more excellent, it is preferably 30 to 100, more preferably 40 to 80, and still more preferably 50 to 60.

A mass ratio of the polycarboxylic acid to the specific sulfonic acid (mass of polycarboxylic acid/mass of specific sulfonic acid) is 70 to 1,000, preferably 70 to 800, more preferably 70 to 600, and particularly preferably 410 to 440.

A mass ratio of the content of the chelating agent to the content of the specific sulfonic acid (content of chelating agent/content of specific sulfonic acid) is preferably 1 to 20.

### Physical Properties of Cleaning Composition

<pH>

A pH of the cleaning composition is 0.10 to 4.00, preferably 0.10 to 3.00 and more preferably 0.10 to 1.50.

The pH of the cleaning composition can be measured by a method based on JIS Z8802-1984 using a known pH meter. A measurement temperature of the pH is 25° C.

Examples of a method of adjusting the pH include a method of adjusting the type and content of each of the components which can be contained in the cleaning composition, and a method of adding a pH adjusting agent described below.

### <Electrical Conductivity>

An electrical conductivity of the cleaning composition is 0.08 to 11.00 mS/cm, preferably 1.00 to 11.00 mS/cm, more preferably 5.00 to 11.00 mS/cm, and still more preferably 8.00 to 10.00 mS/cm.

Examples of a measuring method of the electrical conductivity include a method using an electrical conductivity meter (electrical conductivity meter: portable D-70/ES-70 series, manufactured by HORIBA, Ltd.). A measurement temperature of the electrical conductivity is set to 25° C.

Examples of a method of adjusting the above-described electrical conductivity include a method of adjusting the type and content of each component which can be contained in the cleaning liquid.

### <Content of Metal Impurities>

A content (measured as an ion concentration) of metal impurities (metal elements of Fe, Co, Na, Cu, Mg, Mn, Li, Al, Cr, Ni, Zn, Sn, and Ag) is preferably 5 ppm by mass or less and more preferably 1 ppm by mass or less with respect to the total mass of the cleaning composition. From the viewpoint of applying to the manufacture of state-of-the-art semiconductor elements, the content of the above-described metal impurities is particularly preferably 100 ppb by mass or less and most preferably less than 10 ppb by mass with respect to the total mass of the cleaning composition. The lower limit thereof is preferably 0 ppb by mass or more with respect to the total mass of the cleaning composition.

Among these, a content of Cu ions is preferably 10 ppb by mass or less, more preferably 0.5 ppb by mass or less, and still more preferably 0.2 ppb by mass or less with respect to the total mass of the cleaning composition. The lower limit thereof is preferably 0 ppb by mass or more with respect to the total mass of the cleaning composition.

As a method of measuring the above-described content of the metal impurities, for example, the content can be measured using inductively coupled plasma mass spectrometry (ICP-MS).

Examples of a method for reducing the metal content include performing a purifying treatment such as distillation and filtration using an ion exchange resin or a filter at a stage of raw materials used in the production of the cleaning composition or a stage after the production of the cleaning composition.

Other examples of the method for reducing the metal content include using a container with less elution of impurities, which will be described later, as a container that accommodates the raw material or the produced cleaning composition. In addition, other examples thereof include lining an inner wall of the pipe with a fluororesin to prevent the elution of metal components from a pipe or the like during the production of the cleaning composition.

### <Inorganic Particles and Organic Particles>

The cleaning composition may contain at least one of inorganic particles or organic particles.

The total content of inorganic particles and organic particles is preferably 1.0% by mass or less, more preferably 0.1% by mass or less, and still more preferably 0.01% by mass or less with respect to the total mass of the cleaning composition. The lower limit thereof is preferably 0% by mass or more with respect to the total mass of the cleaning composition.

The inorganic particles and the organic particles contained in the cleaning composition correspond to, for example, particles such as organic solids and inorganic solids contained as impurities in raw materials, and particles such as organic solids and inorganic solids brought in as contaminants during the preparation of the cleaning composition, in which those particles are finally present as particles without being dissolved in the cleaning composition.

The content of the inorganic particles and the organic particles present in the cleaning composition can be measured in a liquid phase by using a commercially available measuring device in a light scattering type liquid particle measuring method using a laser as a light source.

Examples of a method for removing the inorganic particles and the organic particles include a purification treatment such as filtering, which will be described later.

### Amine Compound

The cleaning composition may contain an amine compound.

The amine compound is a compound which has an amino group. The amino group included in the above-described amine compound is at least one amino group selected from the group consisting of a primary amino group (—NH₂), a secondary amino group (>NH), and a tertiary amino group (>N—). In a case where the amine compound has a plurality of classes of amino groups, the amine compound is classified into an amine compound having the highest amino group. Specifically, an amine compound having a primary amino group and a secondary amine group is an amine compound having a secondary amine group.

Examples of the amine compound include an aliphatic amine and an amino alcohol (an aliphatic amine having a hydroxy group). The above-described amine compound may be chain-like (linear or branched) or cyclic.

The amine compound is a compound different from the above-described compounds (for example, the chelating agent).

The amine compound may be used alone or may be used in combination of two or more kinds thereof.

A content of the amine compound is preferably 0.01% to 90.0% by mass, more preferably 0.5% to 65.0% by mass, and still more preferably 1.0% to 25.0% by mass with respect to the total mass of the cleaning composition.

### Anticorrosion Agent

The cleaning composition may contain an anticorrosion agent.

Examples of the anticorrosion agent include compounds having a heteroatom, and a compound having a heterocycle (a heterocyclic compound) is preferable, and a compound having a polycyclic heterocycle is more preferable.

As the anticorrosion agent, a purine compound, an azole compound, or a reducing sulfur compound is preferable.

The anticorrosion agent is preferably a compound different from the above-described compounds which can be contained in the cleaning composition.

The anticorrosion agent may be used alone or in combination of two or more kinds thereof.

A content of the anticorrosion agent is preferably 0.01% to 10.0% by mass, more preferably 1.0% to 10.0% by mass, and still more preferably 5.0% to 8.0% by mass with respect to the total mass of the cleaning composition.

### Surfactant

The cleaning composition may contain a surfactant. The surfactant is a compound different from the above-described compounds (for example, the sulfonic acid having an alkyl group having 9 to 18 carbon atoms).

The surfactant is a compound having a hydrophilic group and a hydrophobic group (lipophilic group) in one molecule, and examples thereof include a nonionic surfactant, an anionic surfactant, a cationic surfactant, and an amphoteric surfactant.

In a case where the cleaning composition contains the surfactant, anticorrosion performance of a metal film and removability of abrasive fine particles are more excellent.

Examples of the surfactant also include compounds described in paragraphs [0092] to of [0096] JP2015-158662A, paragraphs [0045] and [0046] of JP2012-151273A, and paragraphs [0014] to [0020] of JP2009-147389A, the content of which is incorporated herein by reference.

The surfactant may be used alone or in combination of two or more kinds thereof.

From the viewpoint that the performance of the cleaning composition is excellent in a well-balanced, a content of the surfactant is preferably 0.001% to 8.0% by mass, more preferably 0.005% to 5.0% by mass, and still more preferably 0.01 to 3.0% by mass with respect to the total mass of the cleaning composition.

### pH Adjusting Agent

Examples of the pH adjuster include a quaternary ammonium compound, a basic compound, and an acidic compound, and a quaternary ammonium compound, sulfuric acid, or potassium hydroxide is preferable.

The pH of the cleaning composition may be adjusted by adjusting the addition amount of each of the above-described components.

Examples of the pH adjusting agent include paragraphs [0053] and [0054] of WO2019-151141A and paragraph [0021] of WO2019-151001A, the content of which is incorporated herein by reference.

The pH adjusting agent may be used alone or in combination of two or more kinds thereof.

A content of the pH adjusting agent is preferably 0.01% to 10.0% by mass, more preferably 0.05% to 5.0% by mass, and still more preferably 0.05% to 3.0% by mass with respect to the total mass of the cleaning composition.

### Phosphate Ion

The cleaning composition preferably contains a phosphate ion.

The phosphate ion may be contained as an impurity of each of the above-described components.

A content of the phosphate ion is preferably 0.001% to 1.0% by mass, more preferably 0.001% to 0.1% by mass, and still more preferably 0.001% to 0.01% by mass with respect to the total mass of the cleaning composition.

Examples of a method of measuring the above-described content of the phosphate ion include a method of measuring the content of each component in the cleaning composition, which will be described later.

Examples of the method of adjusting the above-described content of the phosphate ion include a method of purifying the components contained in the cleaning composition and the cleaning composition after being adjusted by distillation, use of ion exchange resin, or the like.

### Other Components

The cleaning composition may contain other components.

Examples of the other components include a polymer, an oxidant, a polyhydroxy compound having a molecular weight of 500 or more, a fluorine compound, and an organic solvent.

The other components may be used alone or in combination of two or more kinds thereof.

The content of each of the above-described components in the cleaning composition can be measured according to a known method such as gas chromatography-mass spectrometry (GC-MS), liquid chromatography-mass spectrometry (LC-MS), and ion-exchange chromatography (IC).

### Production of Cleaning Composition

The cleaning composition can be produced by a known method.

It is preferable that a method for producing the cleaning composition includes a liquid preparation step.

### Liquid Preparation Step

The liquid preparation step of the cleaning composition is, for example, a step of preparing the cleaning composition by mixing each of the above-described components which can be contained in the cleaning composition.

There is no particular limitation on the order or timing of mixing together the above-described respective components. Examples of the liquid preparation step include a method in which the polycarboxylic acid, the chelating agent, the specific sulfonic acid, and optional components such as the amine compound as necessary are sequentially added to a container containing purified pure water and then stirred, and the pH adjuster is added thereto as necessary to prepare a solution. The method of adding the pure water and each of the above-described components to the container may be either batch addition or divided addition.

Examples of a stirring method in the liquid preparation step of the cleaning composition include a method of carrying out stirring using a known stirrer or a known disperser.

Examples of the above-described stirrer include an industrial mixer, a portable stirrer, a mechanical stirrer, and a magnetic stirrer. Examples of the above-described disperser include an industrial disperser, a homogenizer, an ultrasonic disperser, and a beads mill.

A storage temperature of the mixing of each of the above-described components in the liquid preparation step of the cleaning composition, a purification treatment described below; and the produced cleaning composition is preferably 40° C. or lower and more preferably 30° C. or lower. The lower limit thereof is preferably 5° C. or higher and more preferably 10° C. or higher. In a case where the storage temperature is within the above-described temperature range, the storage stability of the cleaning composition is excellent.

### <Purification Treatment>

It is preferable that at least one of the raw materials of the cleaning composition is subjected to a purification treatment before the liquid preparation step.

A purity of the raw material after the purification treatment is preferably 99% by mass or more and more preferably 99.9% by mass or more. The upper limit thereof is preferably 99.9999% by mass or less.

Examples of the purification treatment include known methods such as a distillation treatment and a filtering treatment described below, for example, an ion exchange resin, a reverse osmosis membrane (RO membrane), and filtration.

The purification treatment may be carried out by combining a plurality of the above-described purification methods. For example, the raw materials are subjected to a primary purification treatment by passing through the RO membrane, and then the obtained raw materials are subjected to a secondary purification treatment by passing through a purification device consisting of a cation-exchange resin, an anion-exchange resin, or a mixed-bed type ion exchange resin. In addition, the purification treatment may be performed a plurality of times.

Examples of a filter used for the filtering include known filters for filtration.

From the viewpoint of being able to remove highly polar contaminants which tend to cause defects, examples of a material of the filter include fluororesins such as polytetrafluoroethylene (PTFE) and tetrafluoroethylene perfluoroalkyl vinyl ether copolymer (PFA), polyamide-based resins such as nylon, and polyolefin resins (including those with a high density and a ultra-high molecular weight) such as polyethylene and polypropylene (PP). Among these, a polyethylene, a polypropylene (including a high-density polypropylene), a fluororesin (including PTFE and PFA), or a polyamide resin (including nylon) is preferable, and a fluororesin is more preferable.

A critical surface tension of the filter is preferably 70 to 95 mN/m and more preferably 75 to 85 mN/m. In a case where the critical surface tension is within the above-described range, it is possible to remove highly polar contaminants which tend to cause defects. The critical surface tension of the filter is a nominal value of a manufacturer.

A pore diameter of the filter is preferably 2 to 20 nm and more preferably 2 to 15 nm. In a case where the pore diameter of the filter is within the above-described range, it is possible to suppress filtration clogging and to remove fine foreign substances such as impurities and aggregates. The pore diameter of the filter is a nominal value of a manufacturer.

The filtering may be carried out once or twice or more.

In a case where the filtering is carried out twice or more, the filters used for the filtering may be the same or different from each other.

A temperature of the filtering is preferably room temperature (25° C.) or lower, more preferably 23° C. or lower, and still more preferably 20° C. or lower. The lower limit thereof is preferably 0° C. or higher, more preferably 5° C. or higher, and still more preferably 10° C. or higher. In a case where the filtering is carried out in the above range, it is possible to remove foreign substances and impurities dissolved in the raw materials.

### <Container>

The cleaning composition (including the aspect of diluted cleaning composition described later) can be added in any container to be stored and transported as long as the container is not corroded.

In application for a semiconductor, the container is preferably a container which has a high degree of cleanliness inside the container and in which the elution of impurities from an inner wall of an accommodating portion of the container into the cleaning composition is suppressed.

Examples of the above-described container include a commercially available container for a semiconductor cleaning composition. Specific examples thereof include CLEAN BOTTLE series (manufactured by AICELLO CORPORATION) and PURE BOTTLE (manufactured by KODAMA PLASTICS Co., Ltd.).

In addition, the container is preferably a container in which a liquid contact portion with the cleaning composition, such as the inner wall of the accommodating portion of the container, is made of a fluororesin (perfluororesin) or metal subjected to an antirust treatment and a metal elution prevention treatment.

The inner wall of the container is preferably formed from at least one resin selected from the group consisting of a polyethylene resin, a polypropylene resin, and a polyethylene-polypropylene resin: another resin different from these resins: or a metal which has been subjected to an antirust treatment and a metal elution prevention treatment, such as stainless steel, Hastelloy, Inconel, and Monel.

The above-described different resin is preferably a fluororesin (perfluororesin).

With a container having an inner wall formed of a fluororesin is used, elution of ethylene and propylene oligomers can be further suppressed than in a case of a container having an inner wall formed of a polyethylene resin, a polypropylene resin, or a polyethylene-polypropylene resin.

Examples of the container having an inner wall formed of a fluororesin include a FluoroPure PFA composite drum (manufactured by Entegris, Inc.) and containers described 16 of WO99/46309A.

In addition, other than the above-described fluororesin, it is also preferable that the inner wall of the container is made of quartz or a metal material finished up with electropolishing (electropolished metal material).

As a metal material used for producing the electropolished metal material, a metal material containing at least one selected from the group consisting of chromium and nickel, in which the total content of chromium and nickel is more than 25% by mass with respect to the total mass of the metal material, is preferable. Examples thereof include stainless steel and a nickel-chromium alloy.

The total content of chromium and nickel in the metal material is more preferably 30% by mass or more with respect to the total mass of the metal material. The upper limit thereof is preferably 90% by mass or less.

Examples of the method of electropolishing the metal material include known methods.

Examples thereof include methods described in paragraphs [0011] to [0014] of JP2015-227501A and paragraphs [0036] to [0042] of JP2008-264929A.

It is preferable that the inside of the container is cleaned before the container is filled with the cleaning composition.

Examples of the cleaning method include known methods. With regard to a liquid used for the cleaning, it is preferable that the amount of metal impurities in the liquid is reduced. The cleaning composition may be bottled in a container such as a gallon bottle and a coated bottle after the production, and then may be transported and stored.

From the viewpoint of preventing changes in components in the cleaning composition during storage, it is preferable that the inside of the container is replaced with inert gas (for example, nitrogen, argon, or the like) having a purity of 99.99995% by volume or more, and it is more preferable to use inert gas with a low moisture content.

A temperature for transportation and storage may be controlled to normal temperature, or may be controlled to −20° C. to 20° C. from the viewpoint of preventing deterioration.

### Dilution Step

The cleaning composition may be used for cleaning as a cleaning composition (diluted cleaning composition) which has been diluted after undergoing a dilution step of diluting the cleaning composition with a diluent such as water.

The diluted cleaning composition is an aspect of the cleaning composition according to the embodiment of the present invention as long as the requirements of the present invention are satisfied.

A dilution ratio of the cleaning composition in the dilution step can be appropriately adjusted according to the type and content of each component which can be contained in the cleaning composition, the semiconductor substrate as an object to be cleaned, and the like.

The dilution ratio of the diluted cleaning composition to the cleaning composition before the dilution is preferably 10 to 10,000 times, more preferably 20 to 3,000 times, and still more preferably 50 to 1,000 times, in terms of mass ratio or volume ratio (volume ratio at)23° C.

From the viewpoint that it has more excellent defect inhibition performance, the cleaning composition is preferably diluted with water.

That is, it is also preferable that the cleaning composition (diluted cleaning composition) contains each component (excluding water) which can be contained in the above-described cleaning composition in an amount obtained by dividing a suitable content of the each component by the dilution ratio in the above-described range (for example, 100). In other words, the suitable content of each component (excluding water) with respect to the total mass of the diluted cleaning composition is an amount obtained, for example, by dividing the amount described as the suitable content of each component with respect to the total mass of the cleaning composition (cleaning composition before the dilution) by the dilution ratio in the above-described range (for example, 100).

A change in pH before and after the dilution (a difference between the pH of the cleaning composition before the dilution and the pH of the diluted cleaning composition) is preferably 2.5 or less, more preferably 1.8 or less, and still more preferably 1.5 or less. The lower limit thereof is preferably 0.1 or more.

It is preferable that the pH of the cleaning composition before the dilution and the pH of the diluted cleaning composition are each in the above-described suitable aspect.

The dilution step may be carried out according to the above-described liquid preparation step of the cleaning composition. Examples of a stirring device and a stirring method used in the dilution step include known stirring devices and stirring methods used in the above-described liquid preparation step.

It is preferable that the water used in the dilution step is subjected to the purification treatment before use. In addition, it is also preferable to carry out the purification treatment on the diluted cleaning composition obtained in the dilution step.

Examples of the purification treatment include the ion component reducing treatment using the ion exchange resin, the RO membrane, or the like, and the foreign matter removal using filtering, which are described as the purification treatment for the cleaning composition above, and it is preferable to carry out any one of these treatments.

### Clean Room

It is preferable that handlings such as production of the cleaning composition, opening and cleaning of the container, and filling of the cleaning composition, treatment analysis, and measurements are all performed in a clean room.

It is preferable that the clean room meets the 14644-1 clean room standard. It is preferable that the clean room satisfies any one of International Organization for Standardization (ISO) Class 1, ISO Class 2, ISO Class 3, or ISO Class 4, it is more preferable that the clean room satisfies ISO Class 1 or ISO Class 2, and it is still more preferable that the clean room satisfies ISO Class 1.

### Application of Cleaning Composition

The cleaning composition is preferably used in a cleaning step of cleaning a semiconductor substrate, and more preferably used in a cleaning step of cleaning a semiconductor substrate which has been subjected to a CMP treatment. In addition, the cleaning composition can also be used for cleaning a semiconductor substrate in a process of manufacturing a semiconductor substrate.

As described above, for the cleaning of the semiconductor substrate, the diluted cleaning composition obtained by diluting the cleaning composition may be used.

In addition, the cleaning composition according to the embodiment of the present invention is also suitably used for, in addition to the above-described applications, for example, metal cleaning after grinding, LED manufacturing cleaning, TSV bump cleaning, high-density package substrate cleaning, and wafer front opening unify pod (FOUP) cleaning.

### Object to be Cleaned

Examples of an object to be cleaned by the cleaning composition include a semiconductor substrate (for example, a semiconductor substrate having a metal-containing substance).

Examples of a semiconductor substrate having a Cu-containing substance include a semiconductor substrate having a Cu-containing metal wire and/or a Cu-containing plug material.

Examples of a metal contained in the metal-containing substance include at least one metal M selected from the group consisting of Cu (copper), Al (aluminum), Ru (ruthenium), Co (cobalt), W (tungsten), Ti (titanium), Ta (tantalum), Cr (chromium), Hf (hafnium), Os (osmium), Pt (platinum), Ni (nickel), Mn (manganese), Zr (zirconium), Pd (palladium), Mo (molybdenum), La (lanthanum), and Ir (iridium).

The metal-containing substance may be any substance containing a metal (a metal atom), and examples thereof include a single body of the metal M, an alloy containing the metal M, an oxide of the metal M, a nitride of the metal M, and an oxynitride of the metal M.

The metal-containing substance may be a mixture containing two or more of these compounds.

The above-described oxide, the above-described nitride, and the above-described oxynitride may be respectively any of a composite oxide containing the metal, a composite nitride containing the metal, or a composite oxynitride containing the metal.

A content of the metal atom in the metal-containing substance is preferably 10% by mass or more, more preferably 30% by mass or more, and still more preferably 50% by mass or more with respect to the total mass of the metal-containing substance. The upper limit thereof is preferably 100% by mass or less.

The semiconductor substrate preferably has the metal M-containing substance containing the metal M: more preferably has a metal-containing substance containing at least one metal selected from the group consisting of Cu, Al, W, Co, Ti, Ta, Ru, and Mo: still more preferably has a metal-containing substance containing at least one metal selected from the group consisting of Cu, Al, W, Co, Ru, and Mo: and particularly preferably has a metal-containing substance containing Cu metal.

Examples of the semiconductor substrate, which is the object to be cleaned with the cleaning composition, include a substrate having a metal wiring line film, a barrier metal, and an insulating film on a surface of a wafer constituting the semiconductor substrate.

Examples of the wafer constituting the semiconductor substrate include a wafer consisting of a silicon-based material, such as a silicon (Si) wafer, a silicon carbide (SiC) wafer, and a silicon-including resin-based wafer (glass epoxy wafer), a gallium phosphorus (GaP) wafer, a gallium arsenic (GaAs) wafer, and an indium phosphorus (InP) wafer.

Examples of the silicon wafer include an n-type silicon wafer in which a silicon wafer is doped with a pentavalent atom (for example, phosphorus (P), arsenic (As), antimony (Sb), or the like) and a p-type silicon wafer in which a silicon wafer is doped with a trivalent atom (for example, boron (B), gallium (Ga), or the like). Examples of the silicon of the silicon wafer include amorphous silicon, single crystal silicon, polycrystalline silicon, and polysilicon.

Among these, a wafer consisting of a silicon-based material, such as a silicon wafer, a silicon carbide wafer, and a resin-based wafer (a glass epoxy wafer) including silicon, is preferable.

The semiconductor substrate may have an insulating film on the above-described wafer.

Examples of the insulating film include a silicon oxide film (for example, a silicon dioxide (SiO2) film, a tetraethyl orthosilicate (Si(OC₂H₅)₄) film (a TEOS film), a silicon nitride film (for example, silicon nitride (Si3N4), and silicon nitride carbide (SiNC)), and a low-dielectric-constant (Low-k) film (for example, a carbon-doped silicon oxide (SiOC) film and a silicon carbide (SiC) film); and a low-dielectric-constant (Low-k) film is preferable.

The metal-containing substance is also preferably a metal film containing a metal.

The metal film included in the semiconductor substrate is preferably a metal film containing the metal M: more preferably a metal film containing at least one metal selected from the group consisting of Cu, Al, W, Co, Ti, Ta, Ru, and Mo: still more preferably a metal film containing at least one metal selected from the group consisting of Cu, Al, W, Co, Ru, and Mo: and particularly preferably a metal film containing Cu metal.

Examples of the metal film containing at least one metal selected from the group consisting of Cu, Al, W, Co, Ru, and Mo include a film containing copper as a main component (a Cu-containing film), a film containing aluminum as a main component (an Al-containing film), a film containing tungsten as a main component (a W-containing film), a film containing cobalt as a main component (a Co-containing film), a film containing ruthenium as a main component (a Ru-containing film), and a film containing molybdenum as a main component (a Mo-containing film).

The main component means a component of the highest content among components in the metal film.

Examples of the Cu-containing film include a wiring line film consisting of only metal Cu (Cu wiring line film) and a wiring line film made of an alloy consisting of metal Cu and another metal (Cu alloy wiring line film).

Examples of the Cu alloy wiring line film include a wiring line film made of an alloy consisting of at least one metal selected from the group consisting of Al, Ti, Cr, Mn, Ta, and W, and Cu. Specific examples thereof include a Cu—Al alloy wiring line film, a Cu—Ti alloy wiring line film, a Cu—Cr alloy wiring line film, a Cu—Mn alloy wiring line film, a Cu—Ta alloy wiring line film, and a Cu—W alloy wiring line film.

Examples of the Al-containing film (metal film containing Al as a main component) include a metal film consisting of only metal Al (Al metal film) and a metal film made of an alloy consisting of Al and another metal (Al alloy metal film).

Examples of the W-containing film (metal film containing W as a main component) include a metal film consisting of only metal W (W metal film) and a metal film made of an alloy consisting of W and another metal (W alloy metal film).

The W-containing film is used, for example, as a barrier metal or a connecting part between a via and a wiring line.

Examples of the Co-containing film (metal film containing Co as a main component) include a metal film consisting of only metal Co (Co metal film) and a metal film made of an alloy consisting of metal Co and another metal (Co alloy metal film).

Examples of the Co alloy metal film include a metal film made of an alloy consisting of at least one metal selected from the group consisting of Ti, Cr, Fe, Ni, Mo, Pd, Ta, and W, and cobalt. Specific examples thereof include a Co—Ti alloy metal film, a Co—Cr alloy metal film, a Co—Fe alloy metal film, a Co—Ni alloy metal film, a Co—Mo alloy metal film, a Co—Pd alloy metal film, a Co—Ta alloy metal film, and a Co—W alloy metal film.

Examples of the Ru-containing film include a metal film consisting of only metal Ru (Ru metal film) and a metal film made of an alloy consisting of metal Ru and another metal (Ru alloy metal film). The Ru-containing film is often used as a barrier metal.

Examples of the Mo-containing film include a metal film consisting of only metal Mo (Mo metal film) and a metal film made of an alloy consisting of metal Mo and another metal (Mo alloy metal film).

In addition, the cleaning composition is preferably used for cleaning a substrate that has, on a wafer constituting a semiconductor substrate, a metal film (cobalt barrier metal) consisting of only metal Co, which is a barrier metal of the copper-containing wiring line film, and at least a Cu-containing wiring line film, where the Cu-containing wiring line film and the cobalt barrier metal are in contact with each other on the surface of the substrate.

Examples of a method for forming the insulating film, the Ru-containing film, the W-containing film, the Cu-containing film, and the Co-containing film described above on the wafer constituting the semiconductor substrate include known methods.

Examples of the method of forming the insulating film include a method in which the wafer constituting a semiconductor substrate is subjected to a heat treatment in the presence of oxygen gas to form a silicon oxide film, and then a gas of silane and ammonia is introduced thereto to form a silicon nitride film by a chemical vapor deposition (CVD) method.

Examples of the method of forming the Ru-containing film, the W-containing film, the Cu-containing film, and the Co-containing include a method of forming a circuit on a wafer having the above-described insulating film by a known method such as a resist, and then forming a Ru-containing film, a W-containing film, a Cu-containing film, and a Co-containing film according to a method such as plating and a CVD method.

### <CMP Treatment>

The CMP treatment is a treatment in which a surface of a substrate having the metal wiring line film, the barrier metal, and the insulating film is flattened by a combined action of a chemical action and a mechanical polishing using a polishing slurry including polishing fine particles (abrasive grains).

A surface of the semiconductor substrate, which has been subjected to the CMP treatment, may have impurities remaining thereon, such as abrasive grains (for example, silica and alumina) used in the CMP treatment, a polished metal wiring line film, and metal impurities (metal residue, particularly Cu-containing metal residue) derived from the barrier metal. In addition, organic impurities derived from a CMP treatment liquid used in the CMP treatment may remain. For example, since these impurities may cause a short-circuit between wiring lines and deteriorate electrical characteristics of the semiconductor substrate, the semiconductor substrate which has been subjected to the CMP treatment is subjected to a cleaning treatment for removing these impurities from the surface.

Examples of the semiconductor substrate which has been subjected to the CMP treatment include substrates which have been subjected to the CMP treatment, described in Journal of the Japan Society for Precision Engineering, Vol. 84, No. 3, 2018.

### <Buffing Treatment>

The surface of the semiconductor substrate which is the object to be cleaned by the cleaning composition may be subjected to the CMP treatment and then to a buffing treatment.

The buffing treatment is a treatment of reducing impurities on the surface of the semiconductor substrate using a polishing pad. Specifically; the surface of the semiconductor substrate which has been subjected to the CMP treatment is brought into contact with the polishing pad, and the semiconductor substrate and the polishing pad are relatively slid while supplying a composition for the buffing treatment to a contact portion. As a result, impurities on the surface of the semiconductor substrate are removed by a frictional force of the polishing pad and a chemical action of a composition for the buffing treatment.

As the composition for the buffing treatment, a known composition for the buffing treatment can be appropriately used depending on the type of the semiconductor substrate, and the type and amount of the impurities to be removed. Examples of components contained in the composition for a buffing treatment include a water-soluble polymer such as polyvinyl alcohol, water as a dispersion medium, and an acid such as nitric acid.

In addition, as the buffing treatment, it is preferable that the semiconductor substrate is buffed using the above-described cleaning composition as the composition for the buffing treatment.

A polishing device, polishing conditions, and the like, which are used in the buffing treatment, can be appropriately selected from known devices and conditions according to the type of the semiconductor substrate, the object to be removed, and the like. Examples of the buffing treatment include treatments described in paragraphs [0085] to [0088] of WO2017/169539A, the contents of which are incorporated herein by reference.

### Cleaning Method

As the cleaning method using the cleaning composition, a method for cleaning a semiconductor substrate is preferable.

The method for cleaning a semiconductor substrate is not particularly limited as long as it includes a cleaning step of cleaning a substrate using the above-described cleaning composition.

The above-described semiconductor substrate is preferably a semiconductor substrate which has been subjected to the CMP treatment.

The cleaning method of a semiconductor substrate also preferably includes a step of applying the diluted cleaning composition obtained in the above-described dilution step to the semiconductor substrate which has been subjected to the CMP treatment to carry out cleaning.

Examples of the cleaning step of cleaning a semiconductor substrate using the cleaning composition include a known method which is carried out on a CMP-treated semiconductor substrate.

Specifically, in scrub cleaning in which a cleaning member such as a brush is physically brought into contact with a surface of the semiconductor substrate while supplying the cleaning composition to the semiconductor substrate to remove residues, and in immersion-type cleaning such as an immersion in which a semiconductor substrate is immersed in the cleaning composition, a spinning (dropping) in which the cleaning composition is dropped while rotating a semiconductor substrate, and a spraying in which the cleaning composition is sprayed, from the viewpoint that the impurities remaining on the surface of the semiconductor substrate can be further reduced, it is preferable to carry out a ultrasonic treatment to the cleaning composition in which the semiconductor substrate is immersed.

The above-described cleaning step may be carried out once or twice or more. In a case of carrying out the cleaning twice or more, the same method may be repeated or different methods may be combined.

The cleaning method of a semiconductor substrate may be a single-wafer method or a batch method.

The single-wafer method is a method of treating semiconductor substrates one by one, and the batch method is a method of treating a plurality of semiconductor substrates at the same time.

A temperature of the cleaning composition used in for cleaning a semiconductor substrate is not particularly limited.

For example, the temperature may be room temperature (25° C.). From the viewpoint of improving cleaning performance and suppressing damage to members, the temperature is preferably 10° C. to 60° C. and more preferably 15° C. to 50° C.

It is preferable that a pH of the cleaning composition and a pH of the diluted cleaning composition are each in the above-described suitable aspect of pH.

A cleaning time in the cleaning of the semiconductor substrate can be appropriately changed depending on the type, content, and the like of the components contained in the cleaning composition. The above-described cleaning time is preferably 10 to 120 seconds, more preferably 20 to 90 seconds, and still more preferably 30 to 60 seconds.

A supply amount (supply rate) of the cleaning composition in the cleaning step of the semiconductor substrate is preferably 50 to 5,000 mL/min and more preferably 500 to 2,000 mL/min.

In the cleaning of the semiconductor substrate, a mechanical stirring method may be used in order to further improve cleaning ability of the cleaning composition.

Examples of the mechanical stirring method include a method of circulating the cleaning composition on the semiconductor substrate, a method of flowing or spraying the cleaning composition on the semiconductor substrate, and a method of stirring the cleaning composition with ultrasonic or megasonic.

After the above-described cleaning of the semiconductor substrate, a rinsing step of rinsing and washing the semiconductor substrate with a solvent may be carried out.

The rinsing step is preferably a step which is carried out continuously subsequently after the cleaning step of the semiconductor substrate, in which the rinsing is carried out with a rinsing solvent (rinsing liquid) over 5 to 300 seconds. The rinsing step may be carried out using the above-described mechanical stirring method.

Examples of the rinsing solvent include water (preferably deionized water), methanol, ethanol, isopropyl alcohol, N-methylpyrrolidinone, y-butyrolactone, dimethyl sulfoxide, ethyl lactate, and propylene glycol monomethyl ether acetate. In addition, an aqueous rinsing liquid having a pH of more than 8.0 (aqueous ammonium hydroxide which has been diluted, or the like) may be used.

Examples of the method of bringing the rinsing solvent into contact with the semiconductor substrate include the above-described method of bringing the cleaning composition into contact with the cleaning composition.

After the above-described rinsing step, a drying step of drying the semiconductor substrate may be carried out.

Examples of the drying method include a spin drying method, a method of flowing a dry gas onto a semiconductor substrate, a method of heating a substrate by a heating unit such as a hot plate and an infrared lamp, a Marangoni drying method, a Rotagoni drying method, an isopropyl alcohol (IPA) drying method, and a method of combining these methods.

Hereinafter, among applications of the above-described cleaning composition, each application of a cleaning liquid for a semiconductor substrate (preferably a CMP-treated semiconductor substrate), a cleaning liquid for a brush used for cleaning a semiconductor substrate, a cleaning liquid for a polishing pad used in treatment of a semiconductor substrate, and a cleaning liquid for buff cleaning of a CMP-treated semiconductor substrate will be described in detail.

The semiconductor substrate used for the above-described applications is not particularly limited as long as it is the semiconductor substrate described above, but a semiconductor substrate containing tungsten is preferable and a semiconductor substrate having a W-containing film is more preferable.

### First Application: Cleaning of CMP-Treated Semiconductor Substrate

The present composition can be used as a cleaning liquid for a semiconductor substrate in a cleaning method of a semiconductor substrate, which includes a step of cleaning a CMP-treated semiconductor substrate (hereinafter, also referred to as “first application”). That is, the present composition can be used as a cleaning liquid used for a CMP-treated semiconductor substrate in a manufacturing method of a semiconductor element, which includes a step of subjecting a semiconductor substrate with a CMP treatment and a step of cleaning the CMP-treated semiconductor substrate.

The present composition can be applied to a known method performed on the CMP-treated semiconductor substrate.

The present composition used for the first application may be a diluted liquid obtained in the above-described dilution step, and it is also preferable to include a step of applying the diluted liquid to the CMP-treated semiconductor substrate to carry out cleaning.

Examples of the cleaning step of cleaning the CMP-treated semiconductor substrate include the above-described cleaning method.

### Second Application: Cleaning of Cleaning Brush

The present composition can be used as a cleaning liquid for a brush in a cleaning method of a cleaning brush, which includes a step of cleaning a cleaning brush used for cleaning a semiconductor substrate (hereinafter, also referred to as “second application”).

Examples of the cleaning brush which is an object to be cleaned for the second application include known brushes used for scrub cleaning, in which the cleaning brush is physically brought into contact with a surface of the semiconductor substrate to remove residues and the like. As the cleaning brush, a cleaning brush used for cleaning the CMP-treated semiconductor substrate is preferable.

A shape of the cleaning brush is not particularly limited, examples thereof include a cylindrical roll type brush and a pencil type brush, and a roll type brush is preferable. In addition, in many cases, the cleaning brush has a large number of columnar protrusions protruding in a radial direction on the surface.

Examples of a constituent material of the cleaning brush include polymer resins having a hydroxyl group, such as a polyvinyl alcohol (PVA) resin, a polyurethane resin, and a polyolefin resin. As the cleaning brush, a cleaning brush consisting of a sponge-like material of the above-described polymer resin is preferable, and a cleaning brush consisting of a sponge-like material of the PVA resin is more preferable.

Examples of a commercially available product of the cleaning brush include brushes manufactured by Entegris (for example, model “PVP1ARXR1”) and brushes manufactured by AION Co., Ltd. (Bell-eater (registered trademark) A series).

As the method of cleaning the cleaning brush using the composition, a known method carried out in the field of manufacturing a semiconductor element, such as the immersion and spray described as the cleaning step of the semiconductor substrate in the above-described first application is appropriately adopted.

In addition, cleaning conditions including the temperature and cleaning time of the cleaning liquid can also be appropriately selected with reference to the cleaning conditions in the above-described cleaning step of the semiconductor substrate and known cleaning methods, based on the constituent material of the cleaning brush.

Preferred aspects of the composition used for the second application are as follows.

A pH of the composition is preferably within the preferred range of the pH of the composition described above.

The composition used for the second application may be a diluted liquid obtained in the above-described dilution step. A dilution ratio in a case of using a diluted liquid is preferably 10 to 100 times and more preferably 30 to 100 times in terms of mass ratio. A pH of the diluted liquid is preferably within the preferred range of the pH of the diluted liquid described above.

### Third Application: Cleaning of Polishing Pad

The present composition can be used as a cleaning liquid for a polishing pad in a cleaning method of a polishing pad, which includes a step of cleaning a polishing pad used for treating a semiconductor substrate (hereinafter, also referred to as “third application”).

The polishing pad which is an object to be cleaned for the third application is not particularly limited as long as it is a known polishing pad used for treating a semiconductor substrate, and examples thereof include the polishing pad described in <CMP treatment>above. Among these, a polishing pad including a polyurethane resin is preferable. In addition, the polishing pad is preferably a polishing pad used for the CMP treatment.

As the method of cleaning the polishing pad, a known method carried out in the field of manufacturing a semiconductor element, such as the immersion and spray described as the cleaning step of the semiconductor substrate in the above-described first application is appropriately adopted.

In addition, cleaning conditions including the temperature and cleaning time of the cleaning liquid can also be appropriately selected with reference to the cleaning conditions in the above-described cleaning step of the semiconductor substrate and known cleaning methods, based on the constituent material of the polishing pad.

Preferred aspects of the composition used for the third application are as follows.

A pH of the composition is preferably within the preferred range of the pH of the composition described above.

The composition used for the third application may be a diluted liquid obtained in the above-described dilution step. A dilution ratio in a case of using a diluted liquid is preferably 10 to 100 times, more preferably 30 to 100 times, and still more preferably 50 to 100 times in terms of mass ratio. A pH of the diluted liquid is preferably within the preferred range of the pH of the diluted liquid described above.

### Fourth Application: Buff Cleaning

The present composition can be used as a cleaning liquid for buff cleaning in a cleaning method of a semiconductor substrate, which includes a buff cleaning step in which a polishing pad is brought into contact with a surface of a CMP-treated semiconductor substrate to clean the surface of the semiconductor substrate (hereinafter, also referred to as “fourth application”).

A specific method of the buff cleaning for the fourth application is as described above in <Buff cleaning>. In addition, the polishing pad used for the buff cleaning of the fourth application is as described above in <CMP treatment>.

Preferred aspects of the composition used for the fourth application are as follows.

A pH of the composition is preferably within the preferred range of the pH of the composition described above.

The composition used for the fourth application may be a diluted liquid obtained in the above-described dilution step. A dilution ratio in a case of using a diluted liquid is preferably 10 to 100 times, more preferably 30 to 100 times, and still more preferably 50 to 100 times in terms of mass ratio. A pH of the diluted liquid is preferably within the preferred range of the pH of the diluted liquid described above.

It is preferable that the composition is substantially free of abrasive grains and coarse particles.

### Other Applications

The present composition can also be used in applications different from any of the applications of cleaning of the CMP-treated semiconductor substrate, cleaning of the cleaning brush used for cleaning a semiconductor substrate, cleaning of the polishing pad used in treatment of a semiconductor substrate, and buff cleaning of a CMP-treated semiconductor substrate.

### <Cleaning of Semiconductor Substrate Which has Been Subjected to Back Grinding>

For the purpose of reducing the size and thickness of a semiconductor device, there is known a technique (back grinding) of reducing a thickness of a wafer by grinding a surface of the semiconductor substrate opposite to a circuit forming surface.

The present composition can be used as a cleaning liquid in a cleaning step of cleaning a semiconductor substrate which has been subjected to back grinding. By using the present composition, it is possible to remove residues generated by back-grinding and an etching treatment associated with the back grinding.

### <Cleaning of Semiconductor Substrate Which has Been Subjected to Etching Treatment>

In a process of manufacturing a semiconductor element, in a case where a metal layer and/or an insulating layer of a semiconductor substrate is etched by plasma etching using a resist pattern as a mask, residues derived from a photoresist, the metal layer, and the insulating layer are generated on the semiconductor substrate. In addition, in a case where a resist pattern which has been unnecessary is removed by plasma ashing, residues derived from the ashing photoresist are generated on the semiconductor substrate.

The present composition can be used as a cleaning liquid in a cleaning step of cleaning a semiconductor substrate which has been subjected to an etching treatment. By using the present composition, it is possible to remove the etching residues and/or the ashing residues, which are generated on the semiconductor substrate subjected to the etching treatment.

### <Cleaning of Flux Residue on Semiconductor Substrate>

In a case where an electronic component is mounted on a semiconductor substrate by soldering, a flux (accelerator) that removes an oxide which interferes with a connection between a metal such as an electrode or a wiring line and a solder metal and promotes the connection is used. In such a substrate on which the electronic component is soldered using the flux and/or a substrate with a solder bump for soldering the electronic component, which is formed using the flux, residues derived from the flux may remain.

The present composition can be used as a cleaning liquid for cleaning a semiconductor substrate on which the electronic component is soldered using the flux or a semiconductor substrate on which the solder bump is formed using the flux. By using the present composition, it is possible to remove the residues derived from the flux remaining on the semiconductor substrate.

### <Cleaning of Semiconductor Substrate Which has Been Subjected to Bonding Treatment>

In a process of manufacturing a semiconductor element, as a semiconductor chip manufactured by cutting (dicing) a wafer into a predetermined size, semiconductor chips held by a dicing film are picked up one by one, and sent to the next bonding step. During this dicing, foreign matters such as cutting shavings of the wafer and cutting shavings of the dicing film adhere to a surface of the semiconductor chip. In particular, in a bonding step such as flip-chip bonding in which the semiconductor chip is connected to the substrate through terminals arranged on the surface of the semiconductor chip, and direct bonding in which another semiconductor chip is directly bonded on top of the semiconductor chip, it has been known that the quality of bonding deteriorates due to minute foreign matter of several um or less, and a cleaning treatment is carried out to remove the foreign matters from the semiconductor chip subjected to the bonding step.

The present composition can be used as a cleaning liquid in a cleaning step of cleaning a semiconductor chip before being subjected to the bonding step. By using the present composition, it is possible to remove, from the semiconductor chip, the foreign matters such as chips generated in the dicing step before the bonding step.

### <Cleaning of Resin Product>

The present composition can be used for cleaning a resin product, particularly a resin container used for accommodating and transporting a semiconductor substrate in a process of manufacturing a semiconductor element.

In a case of accommodating and transporting a semiconductor substrate, a container for accommodating the semiconductor substrate is used to prevent intrusion of particles and to prevent chemical contamination. Examples of such a container include front opening shipping box (FOSB) used in a case of delivering wafers to semiconductor device manufacturers, and front opening unified pod (FOUP) and standard mechanical interface (SMIF) for storing wafers for transport between wafer processing steps. Here, in a case where an operation of storing the semiconductor substrate in the container and taking out the semiconductor substrate is repeated many times, metal impurities may be generated due to the contact between the semiconductor substrate and the inside of the container. In addition, the inside of the container may be contaminated with residues generated in the manufacturing process of the semiconductor element and remaining on the semiconductor substrate. The inside of the container is cleaned in order to prevent these metal impurities and residues from adhering to the semiconductor substrate.

By using the present composition for cleaning the above-described container, it is possible to remove the etching residues and/or the ashing residues, which are generated on the semiconductor substrate subjected to the etching treatment.

### <Cleaning of Glass Substrate>

The present composition can be used as a cleaning liquid for cleaning liquid a glass substrate, particularly a flat panel display such as a liquid crystal display, a plasma display, an organic EL display, and a touch panel, and a glass substrate suitable for a hard disk. By using the present composition, it is possible to remove residues derived from metal impurities remaining on the glass substrate.

### <Etching Treatment>

The present composition can be used in an etching treatment for removing a metal film on a semiconductor substrate. Examples of the etching treatment include a method of dissolving and removing metal-containing substances on an object by bringing a composition into contact with the semiconductor substrate. The method of bringing the composition into contact with the semiconductor substrate is not particularly limited, and the method described in the first application can be adopted.

For specific aspects of the etching treatment, the description in paragraphs [0049] to [0069] of WO2019/138814A can be adopted, the contents of which are incorporated herein by reference.

### Manufacturing Method of Semiconductor Element

The manufacturing method of a semiconductor element is not particularly limited as long as it is a manufacturing method using the above-described cleaning method, and a known method of manufacturing a semiconductor element can be used.

### EXAMPLES

Hereinafter, the present invention will be described in more detail with reference to Examples. The materials, the amounts of the materials to be used, the proportions, and the like shown in the Examples below may be modified as appropriate as long as the modifications do not depart from the spirit of the present invention. Accordingly, the scope of the present invention should not be construed as being limited to Examples shown below.

In the following Examples, a pH of the cleaning composition was measured at 25° C. using a pH meter (manufactured by HORIBA, Ltd., F-74) in accordance with JIS Z8802-1984. In addition, an electrical conductivity was measured at 25° C. using an electrical conductivity meter (electrical conductivity meter: portable D-70/ES-70 series, manufactured by HORIBA, Ltd.).

In addition, in the production of cleaning compositions of Examples and Comparative Examples, all of handling of a container, and production, filling, storage, and analytical measurement of the cleaning compositions were performed in a clean room satisfying a level of ISO Class 2 or lower.

### Raw Materials of Cleaning Composition

The following components were used to produce a cleaning composition. As various components used in Examples, those all classified into a semiconductor grade or a high-purity grade equivalent thereto were used.

### Polycarboxylic Acid

Citric acid
Oxalic acid
Tartaric acid
Malic acid
Maleic acid

### Chelating Agent

HEDPO: 1-hydroxyethane-1,1-diphosphonic acid
EDTMP: ethylenediaminetetramethylenephosphonic acid
EDTA: ethylenediaminetetraacetic acid

### Specific Sulfonic Acid

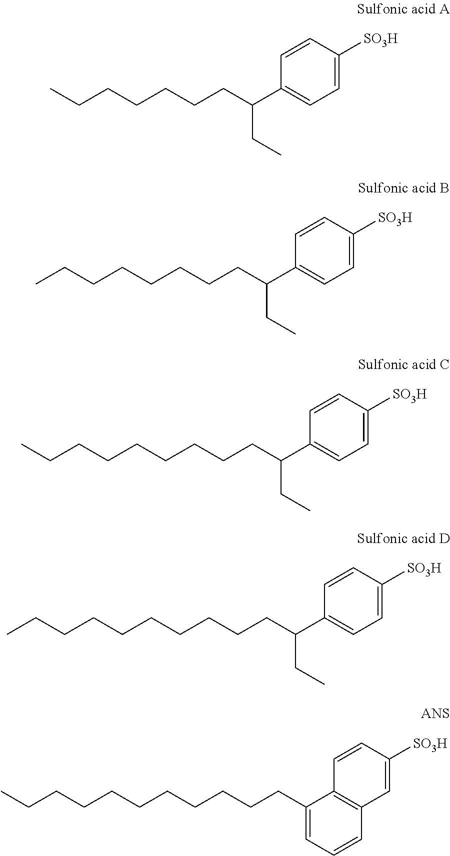 [SMILES: CCCCCCCC(CC)c1ccc(S(=O)(=O)O)cc1 ; CCCCCCCCC(CC)c1ccc(S(=O)(=O)O)cc1 ; CCCCCCCCCC(CC)c1ccc(S(=O)(=O)O)cc1 ; CCCCCCCCCCC(CC)c1ccc(S(=O)(=O)O)cc1 ; CCCCCCCCCCCc1cccc2cc(S(=O)(=O)O)ccc12]

### Water

Water: ultrapure water (manufactured by FUJIFILM Wako Chemicals Corporation)

### Production of Cleaning Composition

The citric acid, HEDPO, and sulfonic acids A to D were added to the ultrapure water in amounts that the finally obtained treatment liquid had the formulation shown in the table below, and then the mixture was sufficiently stirred to obtain a cleaning composition of Example 1.

Cleaning compositions other than Example 1 were each produced according to the production method of Example 1.

The obtained cleaning composition did not contain inorganic particles and organic particles.

### Evaluation

### [Cu Ion]

The Cu ion was adjusted by purifying each component in advance. In the above-described purification method, an object to be purified was passed through an ion exchange resin membrane (ION-CLEAN SL DFAISRPESW44, manufactured by Nihon Pall Corporation) until a predetermined content was reached. The content of the Cu ion was measured under the following measurement conditions using Agilent 8800 triple quadrupole ICP-MS (for semiconductor analysis, option #200).

### (Measurement Condition)

As a sample introduction system, a quartz torch, a coaxial PFA nebulizer (for self-suction), and a platinum interface cone were used. Measurement parameters of cool plasma conditions are as follows.
Radio frequency (RF) output (W): 600
Carrier gas flow rate (L/min): 0.7
Makeup gas flow rate (L/min): 1
Sampling depth (mm): 18

### [Phosphate Ion]

The phosphate ion was adjusted by using each cleaning composition in which each of the components had been purified in advance or by adding phosphonic acid to each cleaning composition. In the above-described purification method, an object to be purified was passed through an ion exchange resin membrane (ION-CLEAN SL DFAISRPESW44, manufactured by Nihon Pall Corporation) until a predetermined content was reached. The content of the phosphate ion was measured by ion exchange chromatography (IC).

### Storage Stability

### <Change in Cleaning Performance Over Time>

Each cleaning composition produced as described above was placed and sealed in a glass container, and the obtained glass container was kept at a temperature of 25° C. and stored for 30 days.

Next, a wafer (diameter: 8 inches) having a metal film made of copper on a surface was polished using FREX300S-II (polishing device, manufactured by Ebara Corporation). The wafer having the metal film made of copper on the surface was polished using, as a polishing liquid, each of CSL9044C (neutral (pH: 6 to 8), silica slurry) and BSL8176C (alkaline, silica slurry) (trade names, both manufactured by FUJIFILM Planar Solutions L.L.C.). As a result, variations in the evaluation of cleaning performance due to the polishing liquid were suppressed. In each of the above-described CMP treatments, the polishing pressure was set to 2.0 psi, the supply rate of the polishing liquid was set to 0.28 mL/(min cm2), and the polishing time was set to 60 seconds. Defects were confirmed after the above-described CMP treatment.

Thereafter, the polished wafer was cleaned over 30 seconds using each of the cleaning compositions after storage for 30 days adjusted to 25° C., and then subjected to a drying treatment.

A defect detection device (ComPlus-II, manufactured by AMAT) was used to measure the number of detections of signal intensities corresponding to defects having a length of more than 0.1 μm on the obtained polished surface of the wafer, thereby calculating the number 30d of defects.

The number 180d of defects was calculated in the same procedure as the number 30d of defects described above, except that, in the number 30d of defects, each cleaning composition was stored for 180 days.

Based on the following expression, a rate of change in the number of defects over time was determined to evaluate a change in cleaning performance over time.

“Rate of change in number of defects over time (%)”=[“Number 180d of defects”/“Number 30d of defects”]×100

As the “Rate of change in the number of defects over time” is closer to 100%, the change in cleaning performance over time is favorable.
8: “Rate of change in the number of defects over time” was 100% or more and less than 106%
7: “Rate of change in the number of defects over time” was 106% or more and less than 108%.
6: “Rate of change in the number of defects over time” was 108% or more and less than 110%.
5: “Rate of change in the number of defects over time” was 110% or more and less than 112%.
4: “Rate of change in the number of defects over time” was 112% or more and less than 114%.
3: “Rate of change in the number of defects over time” was 114% or more and less than 116%.
2: “Rate of change in the number of defects over time” was 116% or more and less than 120%.
1: “Rate of change in the number of defects over time” was 120% or more.

### <Change in Anticorrosion Performance (Cu) Over Time>

Each cleaning composition stored for 30 days or 180 days was prepared in the same manner as in [Change in cleaning performance over time] described above.

A wafer (diameter: 12 inches) having a metal film made of copper on a surface was cut to prepare a 2 cm-square wafer coupon. A thickness of the copper film was set to 200 nm. The wafer coupon was immersed in a sample (temperature: 23° C.) of each cleaning composition produced by the above-described method, and an immersion treatment was performed for 3 minutes at a stirring rotation speed of 250 rpm. Before and after the immersion treatment, the content of copper in each cleaning composition was measured. From the obtained measurement results, a corrosion rate (corrosion rate 30d, unit: A/min) after storage of each cleaning composition for 30 days, and a corrosion rate (corrosion rate 180d, unit: A/min) after storage of each cleaning composition for 180 days were obtained.

Based on the following expression, a rate of change in anticorrosion performance (Cu) over time was determined to evaluate a change in anticorrosion performance (Cu) over time.

“Rate of change in corrosion rate over time (%)”=[“Corrosion rate 180d”/“Corrosion rate 30d”]×100

As the value is closer to 100%, the change in anticorrosion performance (Cu) over time is favorable.
8: “Rate of change in corrosion rate over time” was 100% or more and less than 106%.
7: “Rate of change in corrosion rate over time” was 106% or more and less than 108%.
6: “Rate of change in corrosion rate over time” was 108% or more and less than 110%.
5: “Rate of change in corrosion rate over time” was 110% or more and less than 112%.
4: “Rate of change in corrosion rate over time” was 112% or more and less than 114%.
3: “Rate of change in corrosion rate over time” was 114% or more and less than 116%.
2: “Rate of change in corrosion rate over time” was 116% or more and less than 120%.
1: “Rate of change in corrosion rate over time” was 120% or more.

### Result

In the tables, the column of “Content (% by mass” indicates the content (% by mass) of each component with respect to the total mass of the cleaning composition.

“Sulfonic acid A/sulfonic acid B/sulfonic acid C/sulfonic acid D (10/35/30/25)” and the like in the column of “Type” of “Specific sulfonic acid” indicates the content (% by mass) of each specific sulfonic acid with respect to the content of all specific sulfonic acids. Specifically, a case of “Sulfonic acid A/sulfonic acid B/sulfonic acid C/sulfonic acid D (10/35/30/25)” indicates that, with respect to the content of all specific sulfonic acids, the content of the sulfonic acid A is 10% by mass, the content of the sulfonic acid B is 35% by mass, the content of the sulfonic acid C is 30% by mass, and the content of the sulfonic acid D is 25% by mass.

The column of “A/B” indicates the mass ratio of the content of the polycarboxylic acid to the content of the chelating agent (content of polycarboxylic acid/content of chelating agent).

The column of “A/C” indicates the mass ratio of the content of the polycarboxylic acid to the content of the specific sulfonic acid (content of polycarboxylic acid/content of specific sulfonic acid).

The column of “B/C” indicates the mass ratio of the content of the chelating agent to the content of the specific sulfonic acid (content of chelating agent/content of specific sulfonic acid).

The numerical value in the column of “pH” indicates the pH of the cleaning composition at 25° C. measured by the pH meter.

The “Remainder” of “Water” indicates the remaining components (remainder) which are not the components specified as the components of the cleaning composition in the tables.

TABLE 1

| | Polycarboxylic | | Chelating agent | | | | | | |
|---|---|---|---|---|---|---|---|---|---|
| | acid (A) | | (B) | | Specific sulfonic acid (C) | | | | |
| | | Content | | Content | | Content | | | |
| | | (% by | | (% by | | (% by | | | |
| | Type | mass) | Type | mass) | Type | mass) | A/B | A/C | B/C |
| Example | Citric | 30 | HEDPO | 0.20 | Sulfonic acid | 0.07 | 150 | 428 | 2.86 |
| 101 | acid | | | | A/sulfonic acid | | | | |
| | | | | | B/sulfonic acid | | | | |
| | | | | | C/sulfonic acid D | | | | |
| | | | | | (10/35/30/25) | | | | |
| Example | Citric | 30 | HEDPO | 0.25 | Sulfonic acid | 0.07 | 120 | 428 | 3.57 |
| 102 | acid | | | | A/sulfonic acid | | | | |
| | | | | | B/sulfonic acid | | | | |
| | | | | | C/sulfonic acid D | | | | |
| | | | | | (10/35/30/25) | | | | |
| Example | Citric | 30 | HEDPO | 0.35 | Sulfonic acid | 0.07 | 85 | 428 | 5.00 |
| 103 | acid | | | | A/sulfonic acid | | | | |
| | | | | | B/sulfonic acid | | | | |
| | | | | | C/sulfonic acid D | | | | |
| | | | | | (10/35/30/25) | | | | |
| Example | Citric | 30 | HEDPO | 0.45 | Sulfonic acid | 0.07 | 66 | 428 | 6.43 |
| 104 | acid | | | | A/sulfonic acid | | | | |
| | | | | | B/sulfonic acid | | | | |
| | | | | | C/sulfonic acid D | | | | |
| | | | | | (10/35/30/25) | | | | |
| Example | Citric | 30 | HEDPO | 0.55 | Sulfonic acid | 0.07 | 54 | 428 | 7.86 |
| 105 | acid | | | | A/sulfonic acid | | | | |
| | | | | | B/sulfonic acid | | | | |
| | | | | | C/sulfonic acid D | | | | |
| | | | | | (10/35/30/25) | | | | |
| Example | Citric | 30 | HEDPO | 0.70 | Sulfonic acid | 0.07 | 42 | 428 | 10.00 |
| 106 | acid | | | | A/sulfonic acid | | | | |
| | | | | | B/sulfonic acid | | | | |
| | | | | | C/sulfonic acid D | | | | |
| | | | | | (10/35/30/25) | | | | |
| Example | Citric | 30 | HEDPO | 0.90 | Sulfonic acid | 0.07 | 33 | 428 | 12.86 |
| 107 | acid | | | | A/sulfonic acid | | | | |
| | | | | | B/sulfonic acid | | | | |
| | | | | | C/sulfonic acid D | | | | |
| | | | | | (10/35/30/25) | | | | |
| Example | Citric | 30 | HEDPO | 1.10 | Sulfonic acid | 0.07 | 27 | 428 | 15.71 |
| 108 | acid | | | | A/sulfonic acid | | | | |
| | | | | | B/sulfonic acid | | | | |
| | | | | | C/sulfonic acid D | | | | |
| | | | | | (10/35/30/25) | | | | |
| Example | Citric | 30 | HEDPO | 1.40 | Sulfonic acid | 0.07 | 21 | 428 | 20.00 |
| 109 | acid | | | | A/sulfonic acid | | | | |
| | | | | | B/sulfonic acid | | | | |
| | | | | | C/sulfonic acid D | | | | |
| | | | | | (10/35/30/25) | | | | |
| Example | Citric | 30 | HEDPO | 0.55 | Sulfonic acid | 0.06 | 54 | 500 | 9.17 |
| 110 | acid | | | | A/sulfonic acid | | | | |
| | | | | | B/sulfonic acid | | | | |
| | | | | | C/sulfonic acid D | | | | |
| | | | | | (10/35/30/25) | | | | |

| | | | | | | Storage stability | |
|---|---|---|---|---|---|---|---|
| | | | | | | Change in | Change in |
| | | | Electrical | Cu | Phosphate | cleaning | anticorrosion |
| | | | conductivity | ion | ion | performance | performance |
| | Water | pH | (mS/cm) | (ppb) | (%) | over time | (Cu) over time |
| Example | Remainder | 1.00 | 9.87 | 0.2 | 0.001 | 3 | 8 |
| 101 | | | | | | | |
| Example | Remainder | 1.00 | 9.89 | 0.2 | 0.001 | 4 | 8 |
| 102 | | | | | | | |
| Example | Remainder | 1.00 | 9.92 | 0.2 | 0.001 | 5 | 8 |
| 103 | | | | | | | |
| Example | Remainder | 1.00 | 9.95 | 0.2 | 0.001 | 6 | 8 |
| 104 | | | | | | | |
| Example | Remainder | 1.00 | 9.99 | 0.2 | 0.001 | 8 | 8 |
| 105 | | | | | | | |
| Example | Remainder | 1.00 | 10.03 | 0.2 | 0.001 | 7 | 7 |
| 106 | | | | | | | |
| Example | Remainder | 1.00 | 10.10 | 0.2 | 0.001 | 7 | 6 |
| 107 | | | | | | | |
| Example | Remainder | 1.00 | 10.16 | 0.2 | 0.001 | 7 | 5 |
| 108 | | | | | | | |
| Example | Remainder | 1.00 | 10.26 | 0.2 | 0.001 | 7 | 4 |
| 109 | | | | | | | |
| Example | Remainder | 1.00 | 9.98 | 0.2 | 0.001 | 7 | 7 |
| 110 | | | | | | | |

TABLE 2

| | Polycarboxylic | | Chelating agent | | | | | | |
|---|---|---|---|---|---|---|---|---|---|
| | acid (A) | | (B) | | Specific sulfonic acid (C) | | | | |
| | | Content | | Content | | Content | | | |
| | | (% by | | (% by | | (% by | | | |
| | Type | mass) | Type | mass) | Type | mass) | A/B | A/C | B/C |
| Example | Citric | 30 | HEDPO | 0.55 | Sulfonic acid | 0.05 | 54 | 600 | 11.00 |
| 111 | acid | | | | A/sulfonic acid | | | | |
| | | | | | B/sulfonic acid | | | | |
| | | | | | C/sulfonic acid D | | | | |
| | | | | | (10/35/30/25) | | | | |
| Example | Citric | 30 | HEDPO | 0.55 | Sulfonic acid | 0.04 | 54 | 750 | 13.75 |
| 112 | acid | | | | A/sulfonic acid | | | | |
| | | | | | B/sulfonic acid | | | | |
| | | | | | C/sulfonic acid D | | | | |
| | | | | | (10/35/30/25) | | | | |
| Example | Citric | 30 | HEDPO | 0.55 | Sulfonic acid | 0.03 | 54 | 1000 | 18.33 |
| 113 | acid | | | | A/sulfonic acid | | | | |
| | | | | | B/sulfonic acid | | | | |
| | | | | | C/sulfonic acid D | | | | |
| | | | | | (10/35/30/25) | | | | |
| Example | Citric | 30 | HEDPO | 0.55 | Sulfonic acid | 0.10 | 54 | 300 | 5.50 |
| 114 | acid | | | | A/sulfonic acid | | | | |
| | | | | | B/sulfonic acid | | | | |
| | | | | | C/sulfonic acid D | | | | |
| | | | | | (10/35/30/25) | | | | |
| Example | Citric | 30 | HEDPO | 0.55 | Sulfonic acid | 0.20 | 54 | 150 | 2.75 |
| 115 | acid | | | | A/sulfonic acid | | | | |
| | | | | | B/sulfonic acid | | | | |
| | | | | | C/sulfonic acid D | | | | |
| | | | | | (10/35/30/25) | | | | |
| Example | Citric | 30 | HEDPO | 0.55 | Sulfonic acid | 0.40 | 54 | 75 | 1.38 |
| 116 | acid | | | | A/sulfonic acid | | | | |
| | | | | | B/sulfonic acid | | | | |
| | | | | | C/sulfonic acid D | | | | |
| | | | | | (10/35/30/25) | | | | |
| Example | Citric | 15 | HEDPO | 0.27 | Sulfonic acid | 0.03 | 55 | 500 | 9.00 |
| 117 | acid | | | | A/sulfonic acid | | | | |
| | | | | | B/sulfonic acid | | | | |
| | | | | | C/sulfonic acid D | | | | |
| | | | | | (10/35/30/25) | | | | |
| Example | Citric | 7.0 | HEDPO | 0.14 | Sulfonic acid | 0.02 | 50 | 350 | 7.00 |
| 118 | acid | | | | A/sulfonic acid | | | | |
| | | | | | B/sulfonic acid | | | | |
| | | | | | C/sulfonic acid D | | | | |
| | | | | | (10/35/30/25) | | | | |
| Example | Citric | 3.5 | HEDPO | 0.07 | Sulfonic acid | 0.01 | 50 | 350 | 7.00 |
| 119 | acid | | | | A/sulfonic acid | | | | |
| | | | | | B/sulfonic acid | | | | |
| | | | | | C/sulfonic acid D | | | | |
| | | | | | (10/35/30/25) | | | | |

| | | | | | | Storage stability | |
|---|---|---|---|---|---|---|---|
| | | | | | | Change in | Change in |
| | | | Electrical | Cu | Phosphate | cleaning | anticorrosion |
| | | | conductivity | ion | ion | performance | performance |
| | Water | pH | (mS/cm) | (ppb) | (%) | over time | (Cu) over time |
| Example | Remainder | 1.00 | 9.98 | 0.2 | 0.001 | 7 | 6 |
| 111 | | | | | | | |
| Example | Remainder | 1.00 | 9.98 | 0.2 | 0.001 | 7 | 5 |
| 112 | | | | | | | |
| Example | Remainder | 1.00 | 9.97 | 0.2 | 0.001 | 7 | 4 |
| 113 | | | | | | | |
| Example | Remainder | 1.00 | 9.99 | 0.2 | 0.001 | 6 | 8 |
| 114 | | | | | | | |
| Example | Remainder | 1.00 | 10.03 | 0.2 | 0.001 | 6 | 8 |
| 115 | | | | | | | |
| Example | Remainder | 1.00 | 10.09 | 0.2 | 0.001 | 6 | 8 |
| 116 | | | | | | | |
| Example | Remainder | 1.69 | 4.99 | 0.2 | 0.001 | 6 | 7 |
| 117 | | | | | | | |
| Example | Remainder | 1.71 | 2.33 | 0.2 | 0.001 | 6 | 7 |
| 118 | | | | | | | |
| Example | Remainder | 1.77 | 1.16 | 0.2 | 0.001 | 6 | 7 |
| 119 | | | | | | | |

TABLE 3

| | Polycarboxylic | | Chelating agent | | | | | | |
|---|---|---|---|---|---|---|---|---|---|
| | acid (A) | | (B) | | Specific sulfonic acid (C) | | | | |
| | | Content | | Content | | Content | | | |
| | | (% by | | (% by | | (% by | | | |
| | Type | mass) | Type | mass) | Type | mass) | A/B | A/C | B/C |
| Example | Citric | 1.0 | HEDPO | 0.02 | Sulfonic acid | 0.005 | 50 | 200 | 4.00 |
| 120 | acid | | | | A/sulfonic acid | | | | |
| | | | | | B/sulfonic acid | | | | |
| | | | | | C/sulfonic acid D | | | | |
| | | | | | (10/35/30/25) | | | | |
| Example | Citric | 0.3 | HEDPO | 0.0055 | Sulfonic acid | 0.0007 | 54 | 428 | 7.86 |
| 121 | acid | | | | A/sulfonic acid | | | | |
| | | | | | B/sulfonic acid | | | | |
| | | | | | C/sulfonic acid D | | | | |
| | | | | | (10/35/30/25) | | | | |
| Example | Citric | 30 | EDTMP | 0.55 | Sulfonic acid | 0.07 | 54 | 428 | 7.86 |
| 126 | acid | | | | A/sulfonic acid | | | | |
| | | | | | B/sulfonic acid | | | | |
| | | | | | C/sulfonic acid D | | | | |
| | | | | | (10/35/30/25) | | | | |
| Example | Citric | 30 | EDTA | 0.55 | Sulfonic acid | 0.07 | 54 | 428 | 7.86 |
| 127 | acid | | | | A/sulfonic acid | | | | |
| | | | | | B/sulfonic acid | | | | |
| | | | | | C/sulfonic acid D | | | | |
| | | | | | (10/35/30/25) | | | | |
| Example | Citric | 30 | HEDPO | 0.55 | Sulfonic acid D (100) | 0.07 | 54 | 428 | 7.86 |
| 128 | acid | | | | | | | | |
| Example | Citric | 30 | HEDPO | 0.55 | Sulfonic acid C (100) | 0.07 | 54 | 428 | 7.86 |
| 129 | acid | | | | | | | | |

| | | | | | | Storage stability | |
|---|---|---|---|---|---|---|---|
| | | | | | | Change in | Change in |
| | | | Electrical | Cu | Phosphate | cleaning | anticorrosion |
| | | | conductivity | ion | ion | performance | performance |
| | Water | pH | (mS/cm) | (ppb) | (%) | over time | (Cu) over time |
| Example | Reminder | 1.96 | 0.33 | 0.2 | 0.001 | 5 | 6 |
| 120 | | | | | | | |
| Example | Reminder | 2.64 | 0.09 | 0.2 | 0.001 | 4 | 5 |
| 121 | | | | | | | |
| Example | Reminder | 1.00 | 9.99 | 0.2 | 0.001 | 7 | 7 |
| 126 | | | | | | | |
| Example | Reminder | 1.00 | 9.99 | 0.2 | 0.001 | 7 | 7 |
| 127 | | | | | | | |
| Example | Reminder | 1.00 | 9.99 | 0.2 | 0.001 | 7 | 7 |
| 128 | | | | | | | |
| Example | Reminder | 1.00 | 9.99 | 0.2 | 0.001 | 7 | 7 |
| 129 | | | | | | | |

TABLE 4

| | Polycarboxylic | | Chelating agent | | | | | | |
|---|---|---|---|---|---|---|---|---|---|
| | acid (A) | | (B) | | Specific sulfonic acid (C) | | | | |
| | | Content | | Content | | Content | | | |
| | | (% by | | (% by | | (% by | | | |
| | Type | mass) | Type | mass) | Type | mass) | A/B | A/C | B/C |
| Example | Citric | 30 | HEDPO | 0.55 | Sulfonic acid B (100) | 0.07 | 54 | 428 | 7.86 |
| 130 | acid | | | | | | | | |
| Example | Citric | 30 | HEDPO | 0.55 | Sulfonic acid A (100) | 0.07 | 54 | 428 | 7.86 |
| 131 | acid | | | | | | | | |
| Example | Citric | 30 | HEDPO | 0.55 | ANS (100) | 0.07 | 54 | 428 | 7.86 |
| 132 | acid | | | | | | | | |
| Comparative | Citric | 30 | HEDPO | 0.12 | Sulfonic acid | 0.07 | 250 | 428 | 1.71 |
| Example | acid | | | | A/sulfonic acid | | | | |
| 101 | | | | | B/sulfonic acid | | | | |
| | | | | | C/sulfonic acid D | | | | |
| | | | | | (10/35/30/25) | | | | |
| Comparative | Citric | 30 | HEDPO | 4.00 | Sulfonic acid | 0.07 | 7 | 428 | 57.1 |
| Example | acid | | | | A/sulfonic acid | | | | |
| 102 | | | | | B/sulfonic acid | | | | |
| | | | | | C/sulfonic acid D | | | | |
| | | | | | (10/35/30/25) | | | | |
| Comparative | Citric | 30 | HEDPO | 0.55 | Sulfonic acid | 0.02 | 54 | 1500 | 27.5 |
| Example | acid | | | | A/sulfonic acid | | | | |
| 103 | | | | | B/sulfonic acid | | | | |
| | | | | | C/sulfonic acid D | | | | |
| | | | | | (10/35/30/25) | | | | |
| Comparative | Citric | 30 | HEDPO | 0.55 | Sulfonic acid | 1.50 | 54 | 20 | 0.37 |
| Example | acid | | | | A/sulfonic acid | | | | |
| 104 | | | | | B/sulfonic acid | | | | |
| | | | | | C/sulfonic acid D | | | | |
| | | | | | (10/35/30/25) | | | | |
| Comparative | Citric | 35 | HEDPO | 0.55 | Sulfonic acid | 0.30 | 63 | 116 | 1.83 |
| Example | acid | | | | A/sulfonic acid | | | | |
| 105 | | | | | B/sulfonic acid | | | | |
| | | | | | C/sulfonic acid D | | | | |
| | | | | | (10/35/30/25) | | | | |
| Comparative | Citric | 0.2 | HEDPO | 0.0055 | Sulfonic acid | 0.0007 | 36 | 285 | 7.86 |
| Example | acid | | | | A/sulfonic acid | | | | |
| 106 | | | | | B/sulfonic acid | | | | |
| | | | | | C/sulfonic acid D | | | | |
| | | | | | (10/35/30/25) | | | | |

| | | | | | | Storage stability | |
|---|---|---|---|---|---|---|---|
| | | | | | | Change in | Change in |
| | | | Electrical | Cu | Phosphate | cleaning | anticorrosion |
| | | | conductivity | ion | ion | performance | performance |
| | Water | pH | (mS/cm) | (ppb) | (%) | over time | (Cu) over time |
| Example | Reminder | 1.00 | 9.99 | 0.2 | 0.001 | 7 | 7 |
| 130 | | | | | | | |
| Example | Reminder | 1.00 | 9.99 | 0.2 | 0.001 | 7 | 7 |
| 131 | | | | | | | |
| Example | Reminder | 1.00 | 9.99 | 0.2 | 0.001 | 7 | 7 |
| 132 | | | | | | | |
| Comparative | Reminder | 1.00 | 9.84 | 0.2 | — | 1 | 3 |
| Example | | | | | | | |
| 101 | | | | | | | |
| Comparative | Reminder | 1.00 | 11.11 | 0.2 | — | 3 | 1 |
| Example | | | | | | | |
| 102 | | | | | | | |
| Comparative | Reminder | 1.00 | 9.97 | 0.2 | — | 3 | 1 |
| Example | | | | | | | |
| 103 | | | | | | | |
| Comparative | Reminder | 1.00 | 10.45 | 0.2 | — | 1 | 3 |
| Example | | | | | | | |
| 104 | | | | | | | |
| Comparative | Reminder | 0.99 | 11.69 | 0.2 | — | 1 | 3 |
| Example | | | | | | | |
| 105 | | | | | | | |
| Comparative | Reminder | 2.65 | 0.06 | 0.2 | — | 1 | 3 |
| Example | | | | | | | |
| 106 | | | | | | | |

TABLE 5

| | Polycarboxylic | | Chelating agent | | | | | | |
|---|---|---|---|---|---|---|---|---|---|
| | acid (A) | | (B) | | Specific sulfonic acid (C) | | | | |
| | | Content | | Content | | Content | | | |
| | | (% by | | (% by | | (% by | | | |
| | Type | mass) | Type | mass) | Type | mass) | A/B | A/C | B/C |
| Example | Oxalic | 0.2 | HEDPO | 0.0037 | Sulfonic acid | 0.00047 | 54 | 425 | 7.87 |
| 133 | acid | | | | A/sulfonic acid | | | | |
| | | | | | B/sulfonic acid | | | | |
| | | | | | C/sulfonic acid D | | | | |
| | | | | | (10/35/30/25) | | | | |
| Example | Oxalic | 0.06 | HEDPO | 0.0011 | Sulfonic acid | 0.00014 | 54 | 428 | 7.86 |
| 134 | acid | | | | A/sulfonic acid | | | | |
| | | | | | B/sulfonic acid | | | | |
| | | | | | C/sulfonic acid D | | | | |
| | | | | | (10/35/30/25) | | | | |
| Example | Oxalic | 0.2 | EDTMP | 0.0037 | Sulfonic acid | 0.00047 | 54 | 425 | 7.87 |
| 135 | acid | | | | A/sulfonic acid | | | | |
| | | | | | B/sulfonic acid | | | | |
| | | | | | C/sulfonic acid D | | | | |
| | | | | | (10/35/30/25) | | | | |
| Example | Oxalic | 0.2 | EDTA | 0.0037 | Sulfonic acid | 0.00047 | 54 | 425 | 7.87 |
| 136 | acid | | | | A/sulfonic acid | | | | |
| | | | | | B/sulfonic acid | | | | |
| | | | | | C/sulfonic acid D | | | | |
| | | | | | (10/35/30/25) | | | | |
| Example | Oxalic | 0.2 | HEDPO | 0.0037 | Sulfonic acid D (100) | 0.00047 | 54 | 425 | 7.87 |
| 137 | acid | | | | | | | | |
| Example | Oxalic | 0.2 | HEDPO | 0.0037 | Sulfonic acid C (100) | 0.00047 | 54 | 425 | 7.87 |
| 138 | acid | | | | | | | | |
| Example | Oxalic | 0.2 | HEDPO | 0.0037 | Sulfonic acid B (100) | 0.00047 | 54 | 425 | 7.87 |
| 139 | acid | | | | | | | | |
| Example | Oxalic | 0.2 | HEDPO | 0.0037 | Sulfonic acid A (100) | 0.00047 | 54 | 425 | 7.87 |
| 140 | acid | | | | | | | | |
| Example | Oxalic | 0.2 | HEDPO | 0.0037 | ANS (100) | 0.00047 | 54 | 425 | 7.87 |
| 141 | acid | | | | | | | | |

| | | | | | | Storage stability | |
|---|---|---|---|---|---|---|---|
| | | | | | | Change in | Change in |
| | | | Electrical | Cu | Phosphate | cleaning | anticorrosion |
| | | | conductivity | ion | ion | performance | performance |
| | Water | pH | (mS/cm) | (ppb) | (%) | over time | (Cu) over time |
| Example | Reminder | 2.02 | 5.57 | 0.2 | 0.001 | 7 | 6 |
| 133 | | | | | | | |
| Example | Reminder | 2.24 | 2.21 | 0.2 | 0.001 | 6 | 5 |
| 134 | | | | | | | |
| Example | Reminder | 2.04 | 5.57 | 0.2 | 0.001 | 6 | 5 |
| 135 | | | | | | | |
| Example | Reminder | 1.97 | 5.47 | 0.2 | 0.001 | 6 | 5 |
| 136 | | | | | | | |
| Example | Reminder | 2.02 | 5.57 | 0.2 | 0.001 | 6 | 5 |
| 137 | | | | | | | |
| Example | Reminder | 2.02 | 5.57 | 0.2 | 0.001 | 6 | 5 |
| 138 | | | | | | | |
| Example | Reminder | 2.02 | 5.57 | 0.2 | 0.001 | 6 | 5 |
| 139 | | | | | | | |
| Example | Reminder | 2.02 | 5.57 | 0.2 | 0.001 | 6 | 5 |
| 140 | | | | | | | |
| Example | Reminder | 1.99 | 5.50 | 0.2 | 0.001 | 6 | 5 |
| 141 | | | | | | | |

TABLE 6

| | Polycarboxylic | | Chelating agent | | | | | | |
|---|---|---|---|---|---|---|---|---|---|
| | acid (A) | | (B) | | Specific sulfonic acid (C) | | | | |
| | | Content | | Content | | Content | | | |
| | | (% by | | (% by | | (% by | | | |
| | Type | mass) | Type | mass) | Type | mass) | A/B | A/C | B/C |
| Example | Tartaric | 30 | HEDPO | 0.20 | Sulfonic acid | 0.07 | 150 | 428 | 2.86 |
| 142 | acid | | | | A/sulfonic acid | | | | |
| | | | | | B/sulfonic acid | | | | |
| | | | | | C/sulfonic acid D | | | | |
| | | | | | (10/35/30/25) | | | | |
| Example | Tartaric | 7.0 | HEDPO | 0.13 | Sulfonic acid | 0.016 | 53 | 437 | 8.13 |
| 143 | acid | | | | A/sulfonic acid | | | | |
| | | | | | B/sulfonic acid | | | | |
| | | | | | C/sulfonic acid D | | | | |
| | | | | | (10/35/30/25) | | | | |
| Example | Tartaric | 3.0 | HEDPO | 0.056 | Sulfonic acid | 0.007 | 53 | 428 | 8.00 |
| 144 | acid | | | | A/sulfonic acid | | | | |
| | | | | | B/sulfonic acid | | | | |
| | | | | | C/sulfonic acid D | | | | |
| | | | | | (10/35/30/25) | | | | |
| Example | Tartaric | 1.0 | HEDPO | 0.019 | Sulfonic acid | 0.0023 | 52 | 434 | 8.26 |
| 145 | acid | | | | A/sulfonic acid | | | | |
| | | | | | B/sulfonic acid | | | | |
| | | | | | C/sulfonic acid D | | | | |
| | | | | | (10/35/30/25) | | | | |
| Example | Tartaric | 0.3 | HEDPO | 0.0055 | Sulfonic acid | 0.0007 | 54 | 428 | 7.86 |
| 146 | acid | | | | A/sulfonic acid | | | | |
| | | | | | B/sulfonic acid | | | | |
| | | | | | C/sulfonic acid D | | | | |
| | | | | | (10/35/30/25) | | | | |
| Example | Tartaric | 30 | EDTA | 0.55 | Sulfonic acid | 0.07 | 54 | 428 | 7.86 |
| 147 | acid | | | | A/sulfonic acid | | | | |
| | | | | | B/sulfonic acid | | | | |
| | | | | | C/sulfonic acid D | | | | |
| | | | | | (10/35/30/25) | | | | |
| Example | Tartaric | 7.0 | EDTMP | 0.13 | Sulfonic acid | 0.016 | 53 | 437 | 8.13 |
| 148 | acid | | | | A/sulfonic acid | | | | |
| | | | | | B/sulfonic acid | | | | |
| | | | | | C/sulfonic acid D | | | | |
| | | | | | (10/35/30/25) | | | | |
| Example | Tartaric | 7.0 | EDTA | 0.13 | Sulfonic acid | 0.016 | 53 | 437 | 8.13 |
| 149 | acid | | | | A/sulfonic acid | | | | |
| | | | | | B/sulfonic acid | | | | |
| | | | | | C/sulfonic acid D | | | | |
| | | | | | (10/35/30/25) | | | | |
| Example | Tartaric | 7.0 | HEDPO | 0.13 | Sulfonic acid D (100) | 0.016 | 53 | 437 | 8.13 |
| 150 | acid | | | | | | | | |
| Example | Tartaric | 7.0 | HEDPO | 0.13 | Sulfonic acid C (100) | 0.016 | 53 | 437 | 8.13 |
| 151 | acid | | | | | | | | |
| Example | Tartaric | 7.0 | HEDPO | 0.13 | Sulfonic acid B (100) | 0.016 | 53 | 437 | 8.13 |
| 152 | acid | | | | | | | | |
| Example | Tartaric | 7.0 | HEDPO | 0.13 | Sulfonic acid A (100) | 0.016 | 53 | 437 | 8.13 |
| 153 | acid | | | | | | | | |
| Example | Tartaric | 7.0 | HEDPO | 0.13 | ANS (100) | 0.016 | 53 | 437 | 8.13 |
| 154 | acid | | | | | | | | |

| | | | | | | Storage stability | |
|---|---|---|---|---|---|---|---|
| | | | | | | Change in | Change in |
| | | | Electrical | Cu | Phosphate | cleaning | anticorrosion |
| | | | conductivity | ion | ion | performance | performance |
| | Water | pH | (mS/cm) | (ppb) | (%) | over time | (Cu) over time |
| Example | Reminder | 3.04 | 10.86 | 0.2 | 0.001 | 5 | 5 |
| 142 | | | | | | | |
| Example | Reminder | 1.51 | 7.91 | 0.2 | 0.001 | 6 | 6 |
| 143 | | | | | | | |
| Example | Reminder | 1.69 | 5.90 | 0.2 | 0.001 | 6 | 6 |
| 144 | | | | | | | |
| Example | Reminder | 2.14 | 2.75 | 0.2 | 0.001 | 5 | 5 |
| 145 | | | | | | | |
| Example | Reminder | 2.30 | 1.64 | 0.2 | 0.001 | 4 | 4 |
| 146 | | | | | | | |
| Example | Reminder | 3.07 | 9.62 | 0.2 | 0.001 | 4 | 4 |
| 147 | | | | | | | |
| Example | Reminder | 1.59 | 7.10 | 0.2 | 0.001 | 5 | 5 |
| 148 | | | | | | | |
| Example | Reminder | 1.52 | 6.11 | 0.2 | 0.001 | 5 | 5 |
| 149 | | | | | | | |
| Example | Reminder | 1.51 | 7.91 | 0.2 | 0.001 | 5 | 5 |
| 150 | | | | | | | |
| Example | Reminder | 1.51 | 7.91 | 0.2 | 0.001 | 5 | 5 |
| 151 | | | | | | | |
| Example | Reminder | 1.51 | 7.91 | 0.2 | 0.001 | 5 | 5 |
| 152 | | | | | | | |
| Example | Reminder | 1.51 | 7.91 | 0.2 | 0.001 | 5 | 5 |
| 153 | | | | | | | |
| Example | Reminder | 1.51 | 7.11 | 0.2 | 0.001 | 5 | 5 |
| 154 | | | | | | | |

TABLE 7

| | Polycarboxylic | | Chelating agent | | | | | | |
|---|---|---|---|---|---|---|---|---|---|
| | acid (A) | | (B) | | Specific sulfonic acid (C) | | | | |
| | | Content | | Content | | Content | | | |
| | | (% by | | (% by | | (% by | | | |
| | Type | mass) | Type | mass) | Type | mass) | A/B | A/C | B/C |
| Example | Malic | 30 | HEDPO | 0.20 | Sulfonic acid | 0.07 | 150 | 428 | 2.86 |
| 155 | acid | | | | A/sulfonic acid | | | | |
| | | | | | B/sulfonic acid | | | | |
| | | | | | C/sulfonic acid D | | | | |
| | | | | | (10/35/30/25) | | | | |
| Example | Malic | 30 | HEDPO | 0.25 | Sulfonic acid | 0.07 | 120 | 428 | 3.57 |
| 156 | acid | | | | A/sulfonic acid | | | | |
| | | | | | B/sulfonic acid | | | | |
| | | | | | C/sulfonic acid D | | | | |
| | | | | | (10/35/30/25) | | | | |
| Example | Malic | 30 | HEDPO | 0.35 | Sulfonic acid | 0.07 | 85 | 428 | 5.00 |
| 157 | acid | | | | A/sulfonic acid | | | | |
| | | | | | B/sulfonic acid | | | | |
| | | | | | C/sulfonic acid D | | | | |
| | | | | | (10/35/30/25) | | | | |
| Example | Malic | 30 | HEDPO | 0.45 | Sulfonic acid | 0.07 | 66 | 428 | 6.43 |
| 158 | acid | | | | A/sulfonic acid | | | | |
| | | | | | B/sulfonic acid | | | | |
| | | | | | C/sulfonic acid D | | | | |
| | | | | | (10/35/30/25) | | | | |
| Example | Malic | 30 | HEDPO | 0.55 | Sulfonic acid | 0.07 | 54 | 428 | 7.86 |
| 159 | acid | | | | A/sulfonic acid | | | | |
| | | | | | B/sulfonic acid | | | | |
| | | | | | C/sulfonic acid D | | | | |
| | | | | | (10/35/30/25) | | | | |
| Example | Malic | 30 | HEDPO | 0.70 | Sulfonic acid | 0.07 | 42 | 428 | 10.00 |
| 160 | acid | | | | A/sulfonic acid | | | | |
| | | | | | B/sulfonic acid | | | | |
| | | | | | C/sulfonic acid D | | | | |
| | | | | | (10/35/30/25) | | | | |
| Example | Malic | 30 | HEDPO | 0.90 | Sulfonic acid | 0.07 | 33 | 428 | 12.86 |
| 161 | acid | | | | A/sulfonic acid | | | | |
| | | | | | B/sulfonic acid | | | | |
| | | | | | C/sulfonic acid D | | | | |
| | | | | | (10/35/30/25) | | | | |
| Example | Malic | 30 | HEDPO | 1.10 | Sulfonic acid | 0.07 | 27 | 428 | 15.71 |
| 162 | acid | | | | A/sulfonic acid | | | | |
| | | | | | B/sulfonic acid | | | | |
| | | | | | C/sulfonic acid D | | | | |
| | | | | | (10/35/30/25) | | | | |
| Example | Malic | 30 | HEDPO | 0.55 | Sulfonic acid | 0.06 | 54 | 500 | 9.17 |
| 163 | acid | | | | A/sulfonic acid | | | | |
| | | | | | B/sulfonic acid | | | | |
| | | | | | C/sulfonic acid D | | | | |
| | | | | | (10/35/30/25) | | | | |
| Example | Malic | 30 | HEDPO | 0.55 | Sulfonic acid | 0.05 | 54 | 600 | 11.00 |
| 164 | acid | | | | A/sulfonic acid | | | | |
| | | | | | B/sulfonic acid | | | | |
| | | | | | C/sulfonic acid D | | | | |
| | | | | | (10/35/30/25) | | | | |
| Example | Malic | 30 | HEDPO | 0.55 | Sulfonic acid | 0.04 | 54 | 750 | 13.75 |
| 165 | acid | | | | A/sulfonic acid | | | | |
| | | | | | B/sulfonic acid | | | | |
| | | | | | C/sulfonic acid D | | | | |
| | | | | | (10/35/30/25) | | | | |
| Example | Malic | 30 | HEDPO | 0.55 | Sulfonic acid | 0.03 | 54 | 1000 | 18.33 |
| 166 | acid | | | | A/sulfonic acid | | | | |
| | | | | | B/sulfonic acid | | | | |
| | | | | | C/sulfonic acid D | | | | |
| | | | | | (10/35/30/25) | | | | |
| Example | Malic | 30 | HEDPO | 0.55 | Sulfonic acid | 0.1 | 54 | 300 | 5.50 |
| 167 | acid | | | | A/sulfonic acid | | | | |
| | | | | | B/sulfonic acid | | | | |
| | | | | | C/sulfonic acid D | | | | |
| | | | | | (10/35/30/25) | | | | |
| Example | Malic | 30 | HEDPO | 0.55 | Sulfonic acid | 0.2 | 54 | 150 | 2.75 |
| 168 | acid | | | | A/sulfonic acid | | | | |
| | | | | | B/sulfonic acid | | | | |
| | | | | | C/sulfonic acid D | | | | |
| | | | | | (10/35/30/25) | | | | |

| | | | | | | Storage stability | |
|---|---|---|---|---|---|---|---|
| | | | | | | Change in | Change in |
| | | | Electrical | Cu | Phosphate | cleaning | anticorrosion |
| | | | conductivity | ion | ion | performance | performance |
| | Water | pH | (mS/cm) | (ppb) | (%) | over time | (Cu) over time |
| Example | Reminder | 0.97 | 7.03 | 0.2 | 0.001 | 3 | 7 |
| 155 | | | | | | | |
| Example | Reminder | 0.96 | 7.22 | 0.2 | 0.001 | 3 | 7 |
| 156 | | | | | | | |
| Example | Reminder | 0.93 | 7.61 | 0.2 | 0.001 | 4 | 7 |
| 157 | | | | | | | |
| Example | Reminder | 0.92 | 8.04 | 0.2 | 0.001 | 5 | 7 |
| 158 | | | | | | | |
| Example | Reminder | 0.91 | 8.48 | 0.2 | 0.001 | 7 | 7 |
| 159 | | | | | | | |
| Example | Reminder | 0.88 | 9.00 | 0.2 | 0.001 | 6 | 6 |
| 160 | | | | | | | |
| Example | Reminder | 0.84 | 9.71 | 0.2 | 0.001 | 6 | 5 |
| 161 | | | | | | | |
| Example | Reminder | 0.81 | 10.32 | 0.2 | 0.001 | 6 | 4 |
| 162 | | | | | | | |
| Example | Reminder | 0.89 | 8.30 | 0.2 | 0.001 | 6 | 6 |
| 163 | | | | | | | |
| Example | Reminder | 0.89 | 8.30 | 0.2 | 0.001 | 6 | 5 |
| 164 | | | | | | | |
| Example | Reminder | 0.90 | 8.23 | 0.2 | 0.001 | 6 | 4 |
| 165 | | | | | | | |
| Example | Reminder | 0.90 | 8.16 | 0.2 | 0.001 | 6 | 3 |
| 166 | | | | | | | |
| Example | Reminder | 0.90 | 8.48 | 0.2 | 0.001 | 5 | 7 |
| 167 | | | | | | | |
| Example | Reminder | 0.88 | 8.70 | 0.2 | 0.001 | 5 | 7 |
| 168 | | | | | | | |

TABLE 8

| | Polycarboxylic | | Chelating agent | | | | | | |
|---|---|---|---|---|---|---|---|---|---|
| | acid (A) | | (B) | | Specific sulfonic acid (C) | | | | |
| | | Content | | Content | | Content | | | |
| | | (% by | | (% by | | (% by | | | |
| | Type | mass) | Type | mass) | Type | mass) | A/B | A/C | B/C |
| Example | Malic acid | 30 | HEDPO | 0.55 | Sulfonic acid | 0.4 | 54 | 75 | 1.38 |
| 169 | | | | | A/sulfonic acid | | | | |
| | | | | | B/sulfonic acid | | | | |
| | | | | | C/sulfonic acid D | | | | |
| | | | | | (10/35/30/25) | | | | |
| Example | Malic acid | 15 | HEDPO | 0.28 | Sulfonic acid | 0.035 | 53 | 428 | 8.00 |
| 170 | | | | | A/sulfonic acid | | | | |
| | | | | | B/sulfonic acid | | | | |
| | | | | | C/sulfonic acid D | | | | |
| | | | | | (10/35/30/25) | | | | |
| Example | Malic acid | 7.0 | HEDPO | 0.13 | Sulfonic acid | 0.016 | 53 | 437 | 8.13 |
| 171 | | | | | A/sulfonic acid | | | | |
| | | | | | B/sulfonic acid | | | | |
| | | | | | C/sulfonic acid D | | | | |
| | | | | | (10/35/30/25) | | | | |
| Example | Malic acid | 3.0 | HEDPO | 0.055 | Sulfonic acid | 0.007 | 54 | 428 | 7.86 |
| 172 | | | | | A/sulfonic acid | | | | |
| | | | | | B/sulfonic acid | | | | |
| | | | | | C/sulfonic acid D | | | | |
| | | | | | (10/35/30/25) | | | | |
| Example | Malic acid | 1.0 | HEDPO | 0.019 | Sulfonic acid | 0.0023 | 52 | 434 | 8.26 |
| 173 | | | | | A/sulfonic acid | | | | |
| | | | | | B/sulfonic acid | | | | |
| | | | | | C/sulfonic acid D | | | | |
| | | | | | (10/35/30/25) | | | | |
| Example | Malic acid | 0.3 | HEDPO | 0.0055 | Sulfonic acid | 0.0007 | 54 | 428 | 7.86 |
| 174 | | | | | A/sulfonic acid | | | | |
| | | | | | B/sulfonic acid | | | | |
| | | | | | C/sulfonic acid D | | | | |
| | | | | | (10/35/30/25) | | | | |
| Example | Malic acid | 30 | EDTMP | 0.55 | Sulfonic acid | 0.07 | 54 | 428 | 7.86 |
| 175 | | | | | A/sulfonic acid | | | | |
| | | | | | B/sulfonic acid | | | | |
| | | | | | C/sulfonic acid D | | | | |
| | | | | | (10/35/30/25) | | | | |
| Example | Malic acid | 30 | EDTA | 0.55 | Sulfonic acid | 0.07 | 54 | 428 | 7.86 |
| 176 | | | | | A/sulfonic acid | | | | |
| | | | | | B/sulfonic acid | | | | |
| | | | | | C/sulfonic acid D | | | | |
| | | | | | (10/35/30/25) | | | | |
| Example | Malic acid | 30 | HEDPO | 0.55 | Sulfonic acid D (100) | 0.07 | 54 | 428 | 7.86 |
| 177 | | | | | | | | | |
| Example | Malic acid | 30 | HEDPO | 0.55 | Sulfonic acid C (100) | 0.07 | 54 | 428 | 7.86 |
| 178 | | | | | | | | | |
| Example | Malic acid | 30 | HEDPO | 0.55 | Sulfonic acid B (100) | 0.07 | 54 | 428 | 7.86 |
| 179 | | | | | | | | | |
| Example | Malic acid | 30 | HEDPO | 0.55 | Sulfonic acid A (100) | 0.07 | 54 | 428 | 7.86 |
| 180 | | | | | | | | | |
| Example | Malic acid | 30 | HEDPO | 0.55 | ANS (100) | 0.07 | 54 | 428 | 7.86 |
| 181 | | | | | | | | | |

| | | | | | | Storage stability | |
|---|---|---|---|---|---|---|---|
| | | | | | | Change in | Change in |
| | | | Electrical | Cu | Phosphate | cleaning | anticorrosion |
| | | | conductivity | ion | ion | performance | performance |
| | Water | pH | (mS/cm) | (ppb) | (%) | over time | (Cu) over time |
| Example | Reminder | 0.85 | 9.14 | 0.2 | 0.001 | 5 | 7 |
| 169 | | | | | | | |
| Example | Reminder | 1.32 | 8.09 | 0.2 | 0.001 | 6 | 6 |
| 170 | | | | | | | |
| Example | Reminder | 1.66 | 5.48 | 0.2 | 0.001 | 5 | 6 |
| 171 | | | | | | | |
| Example | Reminder | 1.84 | 4.18 | 0.2 | 0.001 | 5 | 5 |
| 172 | | | | | | | |
| Example | Reminder | 2.29 | 1.92 | 0.2 | 0.001 | 3 | 5 |
| 173 | | | | | | | |
| Example | Reminder | 2.46 | 1.13 | 0.2 | 0.001 | 3 | 3 |
| 174 | | | | | | | |
| Example | Reminder | 0.97 | 7.64 | 0.2 | 0.001 | 6 | 6 |
| 175 | | | | | | | |
| Example | Reminder | 1.04 | 6.26 | 0.2 | 0.001 | 6 | 6 |
| 176 | | | | | | | |
| Example | Reminder | 0.91 | 8.48 | 0.2 | 0.001 | 6 | 6 |
| 177 | | | | | | | |
| Example | Reminder | 0.91 | 8.48 | 0.2 | 0.001 | 6 | 6 |
| 178 | | | | | | | |
| Example | Reminder | 0.91 | 8.48 | 0.2 | 0.001 | 6 | 6 |
| 179 | | | | | | | |
| Example | Reminder | 0.91 | 8.48 | 0.2 | 0.001 | 6 | 6 |
| 180 | | | | | | | |
| Example | Reminder | 0.91 | 8.24 | 0.2 | 0.001 | 6 | 6 |
| 181 | | | | | | | |

TABLE 9

| | Polycarboxylic | | Chelating agent | | | | | | |
|---|---|---|---|---|---|---|---|---|---|
| | acid (A) | | (B) | | Specific sulfonic acid (C) | | | | |
| | | Content | | Content | | Content | | | |
| | | (% by | | (% by | | (% by | | | |
| | Type | mass) | Type | mass) | Type | mass) | A/B | A/C | B/C |
| Example | Maleic | 1.0 | HEDPO | 0.019 | Sulfonic acid | 0.0023 | 52 | 434 | 8.26 |
| 182 | acid | | | | A/sulfonic acid | | | | |
| | | | | | B/sulfonic acid | | | | |
| | | | | | C/sulfonic acid D | | | | |
| | | | | | (10/35/30/25) | | | | |
| Example | Maleic | 0.3 | HEDPO | 0.0056 | Sulfonic acid | 0.0007 | 53 | 428 | 8.00 |
| 183 | acid | | | | A/sulfonic acid | | | | |
| | | | | | B/sulfonic acid | | | | |
| | | | | | C/sulfonic acid D | | | | |
| | | | | | (10/35/30/25) | | | | |
| Example | Maleic | 1.0 | EDTMP | 0.019 | Sulfonic acid | 0.0023 | 52 | 434 | 8.26 |
| 184 | acid | | | | A/sulfonic acid | | | | |
| | | | | | B/sulfonic acid | | | | |
| | | | | | C/sulfonic acid D | | | | |
| | | | | | (10/35/30/25) | | | | |
| Example | Maleic | 1.0 | EDTA | 0.019 | Sulfonic acid | 0.0023 | 52 | 434 | 8.26 |
| 185 | acid | | | | A/sulfonic acid | | | | |
| | | | | | B/sulfonic acid | | | | |
| | | | | | C/sulfonic acid D | | | | |
| | | | | | (10/35/30/25) | | | | |
| Example | Maleic | 1.0 | HEDPO | 0.019 | Sulfonic acid D (100) | 0.0023 | 52 | 434 | 8.26 |
| 186 | acid | | | | | | | | |
| Example | Maleic | 1.0 | HEDPO | 0.019 | Sulfonic acid C (100) | 0.0023 | 52 | 434 | 8.26 |
| 187 | acid | | | | | | | | |
| Example | Maleic | 1.0 | HEDPO | 0.019 | Sulfonic acid B (100) | 0.0023 | 52 | 434 | 8.26 |
| 188 | acid | | | | | | | | |
| Example | Maleic | 1.0 | HEDPO | 0.019 | Sulfonic acid A (100) | 0.0023 | 52 | 434 | 8.26 |
| 189 | acid | | | | | | | | |
| Example | Maleic | 1.0 | HEDPO | 0.019 | ANS (100) | 0.0023 | 52 | 434 | 8.26 |
| 190 | acid | | | | | | | | |

| | | | | | | Storage stability | |
|---|---|---|---|---|---|---|---|
| | | | | | | Change in | Change in |
| | | | Electrical | Cu | Phosphate | cleaning | anticorrosion |
| | | | conductivity | ion | ion | performance | performance |
| | Water | pH | (mS/cm) | (ppb) | (%) | over time | (Cu) over time |
| Example | Reminder | 1.68 | 9.28 | 0.2 | 0.001 | 7 | 7 |
| 182 | | | | | | | |
| Example | Reminder | 1.85 | 5.18 | 0.2 | 0.001 | 6 | 6 |
| 183 | | | | | | | |
| Example | Reminder | 1.69 | 9.38 | 0.2 | 0.001 | 6 | 6 |
| 184 | | | | | | | |
| Example | Reminder | 1.69 | 8.88 | 0.2 | 0.001 | 6 | 6 |
| 185 | | | | | | | |
| Example | Reminder | 1.68 | 9.28 | 0.2 | 0.001 | 6 | 6 |
| 186 | | | | | | | |
| Example | Reminder | 1.68 | 9.28 | 0.2 | 0.001 | 6 | 6 |
| 187 | | | | | | | |
| Example | Reminder | 1.68 | 9.28 | 0.2 | 0.001 | 6 | 6 |
| 188 | | | | | | | |
| Example | Reminder | 1.68 | 9.28 | 0.2 | 0.001 | 6 | 6 |
| 189 | | | | | | | |
| Example | Reminder | 1.69 | 9.38 | 0.2 | 0.001 | 6 | 6 |
| 190 | | | | | | | |

It was confirmed that the cleaning composition according to the embodiment of the present invention had excellent storage stability.

It was confirmed that, in a case where the specific sulfonic acid included the alkylbenzenesulfonic acid A having an alkyl group having 10 carbon atoms, the alkylbenzenesulfonic acid B having an alkyl group having 11 carbon atoms, the alkylbenzenesulfonic acid C having an alkyl group having 12 carbon atoms, and the alkylbenzenesulfonic acid D having an alkyl group having 13 carbon atoms, the effect of the present invention was more excellent (comparison of Examples 105 and 128 to 132, and the like).

It was confirmed that, in a case where the mass ratio of the polycarboxylic acid to the chelating agent was 30 to 100, the effect of the present invention was more excellent (comparison of Examples 101 to 109, and the like).

It was confirmed that, in a case where the mass ratio of the polycarboxylic acid to the specific sulfonic acid was 200 to 600 (70 to 600), the effect of the present invention was more excellent (comparison of Examples 110 to 116, and the like).

### Examples 201 to 206

The above-described storage stability of each of the cleaning compositions shown below was evaluated using a metal film made of tungsten, instead of the metal film made of copper. The CMP treatment in the evaluation of the storage stability using the metal film made of tungsten was performed under conditions (for example, polishing pressure, supply rate of the polishing liquid, polishing time, and the like) under which the same number of defects after the CMP treatment as in the metal film made of copper could be detected. As the polishing liquid, W-2000 (manufactured by Cabot Corporation) was used.

With regard to the evaluation of the storage stability, the cleaning composition of Example 105 was used in Example 201, the cleaning composition of Example 117 was used in Example 202, the cleaning composition of Example 118 was used in Example 203, the cleaning composition of Example 119 was used in Example 204, the cleaning composition of Example 120 was used in Example 205, and the cleaning composition of Example 121 was used in Example 206.

### Examples 301 to 306

The above-described storage stability of each of the cleaning compositions shown below was evaluated using a metal film made of aluminum, instead of the metal film made of copper. The CMP treatment in the evaluation of the storage stability using the metal film made of aluminum was performed under conditions (for example, polishing pressure, supply rate of the polishing liquid, polishing time, and the like) under which the same number of defects after the CMP treatment as in the metal film made of copper could be detected. As the polishing liquid, HS-A (manufactured by SHOWA DENKO K.K.) was used.

With regard to the evaluation of the storage stability, the cleaning composition of Example 105 was used in Example 301, the cleaning composition of Example 117 was used in Example 302, the cleaning composition of Example 118 was used in Example 303, the cleaning composition of Example 119 was used in Example 304, the cleaning composition of Example 120 was used in Example 305, and the cleaning composition of Example 121 was used in Example 306.

### Examples 401 to 406

The above-described storage stability of each of the cleaning compositions shown below was evaluated using a metal film made of cobalt, instead of the metal film made of copper. The CMP treatment in the evaluation of the storage stability using the metal film made of cobalt was performed under conditions (for example, polishing pressure, supply rate of the polishing liquid, polishing time, and the like) under which the same number of defects after the CMP treatment as in the metal film made of copper could be detected. As the polishing liquid, MSL5100C (manufactured by FUJIFILM Planar Solutions L.L.C.) was used.

With regard to the evaluation of the storage stability, the cleaning composition of Example 105 was used in Example 401, the cleaning composition of Example 117 was used in Example 402, the cleaning composition of Example 118 was used in Example 403, the cleaning composition of Example 119 was used in Example 404, the cleaning composition of Example 120 was used in Example 405, and the cleaning composition of Example 121 was used in Example 406.

### Examples 501 to 506

The above-described storage stability of each of the cleaning compositions shown below was evaluated using a metal film made of molybdenum, instead of the metal film made of copper. The CMP treatment in the evaluation of the storage stability using the metal film made of molybdenum was performed under conditions (for example, polishing pressure, supply rate of the polishing liquid, polishing time, and the like) under which the same number of defects after the CMP treatment as in the metal film made of copper could be detected. As the polishing liquid, W-2000 (manufactured by Cabot Corporation) was used.

With regard to the evaluation of the storage stability, the cleaning composition of

Example 105 was used in Example 501, the cleaning composition of Example 117 was used in Example 502, the cleaning composition of Example 118 was used in Example 503, the cleaning composition of Example 119 was used in Example 504, the cleaning composition of Example 120 was used in Example 505, and the cleaning composition of Example 121 was used in Example 506.

### Examples 601 to 606

The above-described storage stability of each of the cleaning compositions shown below was evaluated using a metal film made of ruthenium, instead of the metal film made of copper. The CMP treatment in the evaluation of the storage stability using the metal film made of ruthenium was performed under conditions (for example, polishing pressure, supply rate of the polishing liquid, polishing time, and the like) under which the same number of defects after the CMP treatment as in the metal film made of copper could be detected. As the polishing liquid, W-2000 (manufactured by Cabot Corporation) was used.

With regard to the evaluation of the storage stability, the cleaning composition of Example 105 was used in Example 601, the cleaning composition of Example 117 was used in Example 602, the cleaning composition of Example 118 was used in Example 603, the cleaning composition of Example 119 was used in Example 604, the cleaning composition of Example 120 was used in Example 605, and the cleaning composition of Example 121 was used in Example 606.

TABLE 10

| | Polycarboxylic | | Chelating agent | | | | | | |
|---|---|---|---|---|---|---|---|---|---|
| | acid (A) | | (B) | | Specific sulfonic acid (C) | | | | |
| | | Content | | Content | | Content | | | |
| | | (% by | | (% by | | (% by | | | |
| | Type | mass) | Type | mass) | Type | mass) | A/B | A/C | B/C |
| Example | Citric | 30 | HEDPO | 0.55 | Sulfonic acid | 0.07 | 54 | 428 | 7.86 |
| 201 | acid | | | | A/sulfonic acid | | | | |
| | | | | | B/sulfonic acid | | | | |
| | | | | | C/sulfonic acid D | | | | |
| | | | | | (10/35/30/25) | | | | |
| Example | Citric | 15 | HEDPO | 0.27 | Sulfonic acid | 0.03 | 55 | 500 | 9.00 |
| 202 | acid | | | | A/sulfonic acid | | | | |
| | | | | | B/sulfonic acid | | | | |
| | | | | | C/sulfonic acid D | | | | |
| | | | | | (10/35/30/25) | | | | |
| Example | Citric | 7.0 | HEDPO | 0.14 | Sulfonic acid | 0.02 | 50 | 350 | 7.00 |
| 203 | acid | | | | A/sulfonic acid | | | | |
| | | | | | B/sulfonic acid | | | | |
| | | | | | C/sulfonic acid D | | | | |
| | | | | | (10/35/30/25) | | | | |
| Example | Citric | 3.5 | HEDPO | 0.07 | Sulfonic acid | 0.01 | 50 | 350 | 7.00 |
| 204 | acid | | | | A/sulfonic acid | | | | |
| | | | | | B/sulfonic acid | | | | |
| | | | | | C/sulfonic acid D | | | | |
| | | | | | (10/35/30/25) | | | | |
| Example | Citric | 1.0 | HEDPO | 0.02 | Sulfonic acid | 0.005 | 50 | 200 | 4.00 |
| 205 | acid | | | | A/sulfonic acid | | | | |
| | | | | | B/sulfonic acid | | | | |
| | | | | | C/sulfonic acid D | | | | |
| | | | | | (10/35/30/25) | | | | |
| Example | Citric | 0.3 | HEDPO | 0.0055 | Sulfonic acid | 0.0007 | 54 | 428 | 7.86 |
| 206 | acid | | | | A/sulfonic acid | | | | |
| | | | | | B/sulfonic acid | | | | |
| | | | | | C/sulfonic acid D | | | | |
| | | | | | (10/35/30/25) | | | | |

| | | | | | | Storage stability | |
|---|---|---|---|---|---|---|---|
| | | | | | | Change in | Change in |
| | | | Electrical | Cu | Phosphate | cleaning | anticorrosion |
| | | | conductivity | ion | ion | performance | performance |
| | Water | pH | (mS/cm) | (ppb) | (%) | over time | (Cu) over time |
| Example | Reminder | 1.00 | 9.99 | 0.2 | 0.001 | 7 | 8 |
| 201 | | | | | | | |
| Example | Reminder | 1.69 | 4.99 | 0.2 | 0.001 | 7 | 7 |
| 202 | | | | | | | |
| Example | Reminder | 1.71 | 2.33 | 0.2 | 0.001 | 6 | 7 |
| 203 | | | | | | | |
| Example | Reminder | 1.77 | 1.16 | 0.2 | 0.001 | 6 | 6 |
| 204 | | | | | | | |
| Example | Reminder | 1.96 | 0.33 | 0.2 | 0.001 | 4 | 6 |
| 205 | | | | | | | |
| Example | Reminder | 2.64 | 0.09 | 0.2 | 0.001 | 4 | 4 |
| 206 | | | | | | | |

TABLE 11

| | Polycarboxylic | | Chelating agent | | | | | | |
|---|---|---|---|---|---|---|---|---|---|
| | acid (A) | | (B) | | Specific sulfonic acid (C) | | | | |
| | | Content | | Content | | Content | | | |
| | | (% by | | (% by | | (% by | | | |
| | Type | mass) | Type | mass) | Type | mass) | A/B | A/C | B/C |
| Example | Citric | 30 | HEDPO | 0.55 | Sulfonic acid | 0.07 | 54 | 428 | 7.86 |
| 301 | acid | | | | A/sulfonic acid | | | | |
| | | | | | B/sulfonic acid | | | | |
| | | | | | C/sulfonic acid D | | | | |
| | | | | | (10/35/30/25) | | | | |
| Example | Citric | 15 | HEDPO | 0.27 | Sulfonic acid | 0.03 | 55 | 500 | 9.00 |
| 302 | acid | | | | A/sulfonic acid | | | | |
| | | | | | B/sulfonic acid | | | | |
| | | | | | C/sulfonic acid D | | | | |
| | | | | | (10/35/30/25) | | | | |
| Example | Citric | 7.0 | HEDPO | 0.14 | Sulfonic acid | 0.02 | 50 | 350 | 7.00 |
| 303 | acid | | | | A/sulfonic acid | | | | |
| | | | | | B/sulfonic acid | | | | |
| | | | | | C/sulfonic acid D | | | | |
| | | | | | (10/35/30/25) | | | | |
| Example | Citric | 3.5 | HEDPO | 0.07 | Sulfonic acid | 0.01 | 50 | 350 | 7.00 |
| 304 | acid | | | | A/sulfonic acid | | | | |
| | | | | | B/sulfonic acid | | | | |
| | | | | | C/sulfonic acid D | | | | |
| | | | | | (10/35/30/25) | | | | |
| Example | Citric | 1.0 | HEDPO | 0.02 | Sulfonic acid | 0.005 | 50 | 200 | 4.00 |
| 305 | acid | | | | A/sulfonic acid | | | | |
| | | | | | B/sulfonic acid | | | | |
| | | | | | C/sulfonic acid D | | | | |
| | | | | | (10/35/30/25) | | | | |
| Example | Citric | 0.3 | HEDPO | 0.0055 | Sulfonic acid | 0.0007 | 54 | 428 | 7.86 |
| 306 | acid | | | | A/sulfonic acid | | | | |
| | | | | | B/sulfonic acid | | | | |
| | | | | | C/sulfonic acid D | | | | |
| | | | | | (10/35/30/25) | | | | |

| | | | | | | Storage stability | |
|---|---|---|---|---|---|---|---|
| | | | | | | Change in | Change in |
| | | | Electrical | Cu | Phosphate | cleaning | anticorrosion |
| | | | conductivity | ion | ion | performance | performance |
| | Water | pH | (mS/cm) | (ppb) | (%) | over time | (Cu) over time |
| Example | Reminder | 1.00 | 9.99 | 0.2 | 0.001 | 7 | 8 |
| 301 | | | | | | | |
| Example | Reminder | 1.69 | 4.99 | 0.2 | 0.001 | 6 | 8 |
| 302 | | | | | | | |
| Example | Reminder | 1.71 | 2.33 | 0.2 | 0.001 | 6 | 7 |
| 303 | | | | | | | |
| Example | Reminder | 1.77 | 1.16 | 0.2 | 0.001 | 5 | 7 |
| 304 | | | | | | | |
| Example | Reminder | 1.96 | 0.33 | 0.2 | 0.001 | 5 | 5 |
| 305 | | | | | | | |
| Example | Reminder | 2.64 | 0.09 | 0.2 | 0.001 | 4 | 4 |
| 306 | | | | | | | |

TABLE 12

| | Polycarboxylic | | Chelating agent | | | | | | |
|---|---|---|---|---|---|---|---|---|---|
| | acid (A) | | (B) | | Specific sulfonic acid (C) | | | | |
| | | Content | | Content | | Content | | | |
| | | (% by | | (% by | | (% by | | | |
| | Type | mass) | Type | mass) | Type | mass) | A/B | A/C | B/C |
| Example | Citric | 30 | HEDPO | 0.55 | Sulfonic acid | 0.07 | 54 | 428 | 7.86 |
| 401 | acid | | | | A/sulfonic acid | | | | |
| | | | | | B/sulfonic acid | | | | |
| | | | | | C/sulfonic acid D | | | | |
| | | | | | (10/35/30/25) | | | | |
| Example | Citric | 15 | HEDPO | 0.27 | Sulfonic acid | 0.03 | 55 | 500 | 9.00 |
| 402 | acid | | | | A/sulfonic acid | | | | |
| | | | | | B/sulfonic acid | | | | |
| | | | | | C/sulfonic acid D | | | | |
| | | | | | (10/35/30/25) | | | | |
| Example | Citric | 7.0 | HEDPO | 0.14 | Sulfonic acid | 0.02 | 50 | 350 | 7.00 |
| 403 | acid | | | | A/sulfonic acid | | | | |
| | | | | | B/sulfonic acid | | | | |
| | | | | | C/sulfonic acid D | | | | |
| | | | | | (10/35/30/25) | | | | |
| Example | Citric | 3.5 | HEDPO | 0.07 | Sulfonic acid | 0.01 | 50 | 350 | 7.00 |
| 404 | acid | | | | A/sulfonic acid | | | | |
| | | | | | B/sulfonic acid | | | | |
| | | | | | C/sulfonic acid D | | | | |
| | | | | | (10/35/30/25) | | | | |
| Example | Citric | 1.0 | HEDPO | 0.02 | Sulfonic acid | 0.005 | 50 | 200 | 4.00 |
| 405 | acid | | | | A/sulfonic acid | | | | |
| | | | | | B/sulfonic acid | | | | |
| | | | | | C/sulfonic acid D | | | | |
| | | | | | (10/35/30/25) | | | | |
| Example | Citric | 0.3 | HEDPO | 0.0055 | Sulfonic acid | 0.0007 | 54 | 428 | 7.86 |
| 406 | acid | | | | A/sulfonic acid | | | | |
| | | | | | B/sulfonic acid | | | | |
| | | | | | C/sulfonic acid D | | | | |
| | | | | | (10/35/30/25) | | | | |

| | | | | | | Storage stability | |
|---|---|---|---|---|---|---|---|
| | | | | | | Change in | Change in |
| | | | Electrical | Cu | Phosphate | cleaning | anticorrosion |
| | | | conductivity | ion | ion | performance | performance |
| | Water | pH | (mS/cm) | (ppb) | (%) | over time | (Cu) over time |
| Example | Reminder | 1.00 | 9.99 | 0.2 | 0.001 | 7 | 8 |
| 401 | | | | | | | |
| Example | Reminder | 1.69 | 4.99 | 0.2 | 0.001 | 6 | 8 |
| 402 | | | | | | | |
| Example | Reminder | 1.71 | 2.33 | 0.2 | 0.001 | 5 | 7 |
| 403 | | | | | | | |
| Example | Reminder | 1.77 | 1.16 | 0.2 | 0.001 | 5 | 7 |
| 404 | | | | | | | |
| Example | Reminder | 1.96 | 0.33 | 0.2 | 0.001 | 4 | 6 |
| 405 | | | | | | | |
| Example | Reminder | 2.64 | 0.09 | 0.2 | 0.001 | 4 | 4 |
| 406 | | | | | | | |

TABLE 13

| | Polycarboxylic | | Chelating agent | | | | | | |
|---|---|---|---|---|---|---|---|---|---|
| | acid (A) | | (B) | | Specific sulfonic acid (C) | | | | |
| | | Content | | Content | | Content | | | |
| | | (% by | | (% by | | (% by | | | |
| | Type | mass) | Type | mass) | Type | mass) | A/B | A/C | B/C |
| Example | Citric | 30 | HEDPO | 0.55 | Sulfonic acid | 0.07 | 54 | 428 | 7.86 |
| 501 | acid | | | | A/sulfonic acid | | | | |
| | | | | | B/sulfonic acid | | | | |
| | | | | | C/sulfonic acid D | | | | |
| | | | | | (10/35/30/25) | | | | |
| Example | Citric | 15 | HEDPO | 0.27 | Sulfonic acid | 0.03 | 55 | 500 | 9.00 |
| 502 | acid | | | | A/sulfonic acid | | | | |
| | | | | | B/sulfonic acid | | | | |
| | | | | | C/sulfonic acid D | | | | |
| | | | | | (10/35/30/25) | | | | |
| Example | Citric | 7.0 | HEDPO | 0.14 | Sulfonic acid | 0.02 | 50 | 350 | 7.00 |
| 503 | acid | | | | A/sulfonic acid | | | | |
| | | | | | B/sulfonic acid | | | | |
| | | | | | C/sulfonic acid D | | | | |
| | | | | | (10/35/30/25) | | | | |
| Example | Citric | 3.5 | HEDPO | 0.07 | Sulfonic acid | 0.01 | 50 | 350 | 7.00 |
| 504 | acid | | | | A/sulfonic acid | | | | |
| | | | | | B/sulfonic acid | | | | |
| | | | | | C/sulfonic acid D | | | | |
| | | | | | (10/35/30/25) | | | | |
| Example | Citric | 1.0 | HEDPO | 0.02 | Sulfonic acid | 0.005 | 50 | 200 | 4.00 |
| 505 | acid | | | | A/sulfonic acid | | | | |
| | | | | | B/sulfonic acid | | | | |
| | | | | | C/sulfonic acid D | | | | |
| | | | | | (10/35/30/25) | | | | |
| Example | Citric | 0.3 | HEDPO | 0.0055 | Sulfonic acid | 0.0007 | 54 | 428 | 7.86 |
| 506 | acid | | | | A/sulfonic acid | | | | |
| | | | | | B/sulfonic acid | | | | |
| | | | | | C/sulfonic acid D | | | | |
| | | | | | (10/35/30/25) | | | | |

| | | | | | | Storage stability | |
|---|---|---|---|---|---|---|---|
| | | | | | | Change in | Change in |
| | | | Electrical | Cu | Phosphate | cleaning | anticorrosion |
| | | | conductivity | ion | ion | performance | performance |
| | Water | pH | (mS/cm) | (ppb) | (%) | over time | (Cu) over time |
| Example | Reminder | 1.00 | 9.99 | 0.2 | 0.001 | 8 | 7 |
| 501 | | | | | | | |
| Example | Reminder | 1.69 | 4.99 | 0.2 | 0.001 | 7 | 7 |
| 502 | | | | | | | |
| Example | Reminder | 1.71 | 2.33 | 0.2 | 0.001 | 6 | 6 |
| 503 | | | | | | | |
| Example | Reminder | 1.77 | 1.16 | 0.2 | 0.001 | 6 | 6 |
| 504 | | | | | | | |
| Example | Reminder | 1.96 | 0.33 | 0.2 | 0.001 | 5 | 5 |
| 505 | | | | | | | |
| Example | Reminder | 2.64 | 0.09 | 0.2 | 0.001 | 4 | 4 |
| 506 | | | | | | | |

TABLE 14

| | Polycarboxylic | | Chelating agent | | | | | | |
|---|---|---|---|---|---|---|---|---|---|
| | acid (A) | | (B) | | Specific sulfonic acid (C) | | | | |
| | | Content | | Content | | Content | | | |
| | | (% by | | (% by | | (% by | | | |
| | Type | mass) | Type | mass) | Type | mass) | A/B | A/C | B/C |
| Example | Citric | 30 | HEDPO | 0.55 | Sulfonic acid | 0.07 | 54 | 428 | 7.86 |
| 601 | acid | | | | A/sulfonic acid | | | | |
| | | | | | B/sulfonic acid | | | | |
| | | | | | C/sulfonic acid D | | | | |
| | | | | | (10/35/30/25) | | | | |
| Example | Citric | 15 | HEDPO | 0.27 | Sulfonic acid | 0.03 | 55 | 500 | 9.00 |
| 602 | acid | | | | A/sulfonic acid | | | | |
| | | | | | B/sulfonic acid | | | | |
| | | | | | C/sulfonic acid D | | | | |
| | | | | | (10/35/30/25) | | | | |
| Example | Citric | 7.0 | HEDPO | 0.14 | Sulfonic acid | 0.02 | 50 | 350 | 7.00 |
| 603 | acid | | | | A/sulfonic acid | | | | |
| | | | | | B/sulfonic acid | | | | |
| | | | | | C/sulfonic acid D | | | | |
| | | | | | (10/35/30/25) | | | | |
| Example | Citric | 3.5 | HEDPO | 0.07 | Sulfonic acid | 0.01 | 50 | 350 | 7.00 |
| 604 | acid | | | | A/sulfonic acid | | | | |
| | | | | | B/sulfonic acid | | | | |
| | | | | | C/sulfonic acid D | | | | |
| | | | | | (10/35/30/25) | | | | |
| Example | Citric | 1.0 | HEDPO | 0.02 | Sulfonic acid | 0.005 | 50 | 200 | 4.00 |
| 605 | acid | | | | A/sulfonic acid | | | | |
| | | | | | B/sulfonic acid | | | | |
| | | | | | C/sulfonic acid D | | | | |
| | | | | | (10/35/30/25) | | | | |
| Example | Citric | 0.3 | HEDPO | 0.0055 | Sulfonic acid | 0.0007 | 54 | 428 | 7.86 |
| 606 | acid | | | | A/sulfonic acid | | | | |
| | | | | | B/sulfonic acid | | | | |
| | | | | | C/sulfonic acid D | | | | |
| | | | | | (10/35/30/25) | | | | |

| | | | | | | Storage stability | |
|---|---|---|---|---|---|---|---|
| | | | | | | Change in | Change in |
| | | | Electrical | Cu | Phosphate | cleaning | anticorrosion |
| | | | conductivity | ion | ion | performance | performance |
| | Water | pH | (mS/cm) | (ppb) | (%) | over time | (Cu) over time |
| Example | Reminder | 1.00 | 9.99 | 0.2 | 0.001 | 7 | 7 |
| 601 | | | | | | | |
| Example | Reminder | 1.69 | 4.99 | 0.2 | 0.001 | 6 | 7 |
| 602 | | | | | | | |
| Example | Reminder | 1.71 | 2.33 | 0.2 | 0.001 | 5 | 6 |
| 603 | | | | | | | |
| Example | Reminder | 1.77 | 1.16 | 0.2 | 0.001 | 5 | 6 |
| 604 | | | | | | | |
| Example | Reminder | 1.96 | 0.33 | 0.2 | 0.001 | 4 | 5 |
| 605 | | | | | | | |
| Example | Reminder | 2.64 | 0.09 | 0.2 | 0.001 | 4 | 4 |
| 606 | | | | | | | |

It was confirmed that, with the cleaning composition according to the embodiment of the present invention, the effect of the present invention was obtained even in a case where an object to be cleaned is other than copper.

In a case where the cleaning composition of each of Examples was used for the applications described above (cleaning of the cleaning brush, cleaning of the polishing pad, buff cleaning, cleaning of the semiconductor substrate which had been subjected to back grinding, cleaning of the semiconductor substrate which had been subjected to an etching treatment, cleaning of flux residues on the semiconductor substrate, cleaning of the semiconductor substrate which had been subjected to a bonding treatment, cleaning of the resin product, cleaning of the glass substrate, and the etching treatment), it was confirmed that the cleaning compositions of Examples were all excellent in cleaning performance than the cleaning compositions of Comparative Examples.

What is claimed is:

1. A cleaning composition comprising:
a polycarboxylic acid;
a chelating agent;
a sulfonic acid having an alkyl group having 9 to 18 carbon atoms; and
water,
wherein a mass ratio of the polycarboxylic acid to the chelating agent is 10 to 200,
a mass ratio of the polycarboxylic acid to the sulfonic acid is 70 to 1,000,
a pH of the cleaning composition is 0.10 to 4.00, and
an electrical conductivity of the cleaning composition is 0.08 to 11.00 mS/cm.

2. The cleaning composition according to claim 1,
wherein the polycarboxylic acid includes a polycarboxylic acid having two or three carboxy groups.

3. The cleaning composition according to claim 1,
wherein the polycarboxylic acid further includes a polycarboxylic acid having a hydroxy group.

4. The cleaning composition according to claim 1,
wherein the polycarboxylic acid includes citric acid.

5. The cleaning composition according to claim 1,
wherein a content of the polycarboxylic acid is 0.1% to 35% by mass with respect to a total mass of the cleaning composition.

6. The cleaning composition according to claim 1,
wherein the sulfonic acid is alkylbenzenesulfonic acid.

7. The cleaning composition according to claim 1,
wherein the sulfonic acid has any alkyl group having 10 to 13 carbon atoms.

8. The cleaning composition according to claim 1,
wherein the sulfonic acid includes an alkylbenzenesulfonic acid A having an alkyl group having 10 carbon atoms, an alkylbenzenesulfonic acid B having an alkyl group having 11 carbon atoms, an alkylbenzenesulfonic acid C having an alkyl group having 12 carbon atoms, and an alkylbenzenesulfonic acid D having an alkyl group having 13 carbon atoms.

9. The cleaning composition according to claim 8,
wherein a content of the alkylbenzenesulfonic acid B is 20% to 50% by mass with respect to a total mass of the alkylbenzenesulfonic acids A to D.

10. The cleaning composition according to claim 1,
wherein the chelating agent has a phosphonate group.

11. The cleaning composition according to claim 1,
wherein the mass ratio of the polycarboxylic acid to the chelating agent is 30 to 100.

12. The cleaning composition according to claim 1,
wherein the mass ratio of the polycarboxylic acid to the sulfonic acid is 70 to 600.

13. The cleaning composition according to claim 1, further comprising:
a phosphate ion,
wherein a content of the phosphate ion is 0.001% to 1.0% by mass with respect to a total mass of the cleaning composition.

14. A cleaning method of a semiconductor substrate, comprising:
cleaning a semiconductor substrate with the cleaning composition according to claim 1.

15. A manufacturing method of a semiconductor element, comprising:
the cleaning method of a semiconductor substrate according to claim 14.
